(19) United States
(12) Patent Application Publication
(10) Pub. No.: US 2007/0053420 A1
(43) Pub. Date: Mar. 8, 2007

(54) Method, apparatus, and program for designing digital filters

(75) Inventor: Yukio Koyanagi, Saitama-shi (JP)

Correspondence Address: CONNOLLY BOVE LODGE & HUTZ LLP, P.O. BOX 2207, WILMINGTON, DE, 19899-2207, US

(73) Assignee: Neuro Solution Corp., Tokyo (JP)

(21) Appl. No.: 11/465,056

(22) Filed: Aug. 16, 2006

Related U.S. Application Data
(63) Continuation of application No. PCT/JP04/15562, filed on Oct. 14, 2004.

(30) Foreign Application Priority Data
Feb. 17, 2004 (JP) 2004-039779

(51) Int. Cl. H03K 5/159

(52) U.S. Cl. 375/232

(57) ABSTRACT

For example, more than one FIR-type basic filters having a symmetric sequence of numbers having a predetermined characteristic as filter coefficient are combined and connected in cascade connection. The filter coefficients are calculated and for the y-bits data of the calculated filter coefficients, the lower bits are cut off for rounding so as to obtain filter coefficients of x-bits (x<y). Thus, it is possible to significantly reduce unnecessary filter coefficients without performing the conventional window multiplication. Moreover, it is possible to realize a digital filter having a desired frequency characteristic with a small circuit size and with a high accuracy without causing a truncation error attributed to window multiplication in the frequency characteristic.

### TECHNICAL FIELD

The present invention relates to a designing method of digital filters as well as apparatuses and a program for designing digital filters as well as digital filters, and in particular relates to an FIR filter of a type having a tapped delay line composed of multiple delay units and increasing several times in output signals of respective taps and thereafter adding the result of those multiplications to output them as well as a method of designing it.

### BACKGROUND ART

Various kinds of electronical devices provided in a variety of technical fields normally implement digital signal processing of some sort in their inside. The most important basic operations of digital signal processing include filtering processing of taking only signals within a required certain frequency band out of input signals in which respective kinds of signals and noises are mixed. Therefore, digital filters are frequently used in electronics devices of implementing digital signal processing.

IIR (Infinite Impulse Response) filters and FIR (Finite Impulse Response) filters are mostly used as digital filters. Among them, the FIR filters are advantageous as follows. Firstly the circuit is always stable since the pole of transfer function of an FIR filter is located only in the origin of the z plane. Secondly, if the filter coefficients are of a symmetrical type, it is possible to realize a completely accurate linear-phase characteristic.

In this FIR filter, the impulse response expressed in finite time length will straight be the filter coefficients. Accordingly, designing an FIR filter means to determine the filter coefficients so as to obtain a desired frequency characteristic. Conventionally, at the time of designing an FIR filter, the filter coefficients are calculated based on the target frequency characteristic and window multiplication is performed thereon to derive finite units of coefficient groups. And designing used to be implemented in a method of transforming the derived coefficient groups with FFT (fast Fourier transform) into a frequency characteristic and confirming whether or not this satisfies the target characteristic.

At the time of calculating filter coefficients from the target frequency, an operation of convolution and the like, for example, in use of a window function and Chebyshev approximation formula based on proportion of sampling frequency to cutoff frequency used to be performed. The number of coefficients derived thereby will become significantly large. Using all of those coefficients, the number of taps and multipliers for a filter circuit will become significantly large, which is not realistic. Therefore, the number of filter coefficients needed to be reduced with window multiplication to such a practically endurable level.

However, the frequency characteristic of the FIR filter derived by a conventional designing method depends on the window function and the approximation formula. Therefore unless they are well set, a target good frequency characteristic cannot be derived. However, appropriate setting of window functions and approximation formulas is generally difficult. In addition, window multiplication in order to reduce the number of filter coefficients will cause a truncation error on the frequency characteristic. Therefore, there used to be such a problem that realization of a desired frequency characteristic with a conventional filter designing method is very difficult.

In addition, in order to design an FIR filter of realizing a desired frequency characteristic as accurately as possible, the number of filter coefficients that can be reduced by window multiplication is limited. Therefore, the number of taps of the designed FIR filter will become very large and further more the filter coefficient value thereof will become very complicated and random value. Therefore, there used to be a problem that a large scaled circuit configuration (adder and multiplier) will become necessary in order to realize the number of taps as well as filter coefficient values thereof.

In addition, in order to derive a desired frequency characteristic with a conventional filter designing method, a trial and error practice while causing tentatively derived filter coefficients to undergo FFT to confirm its frequency characteristic will be required. Accordingly, conventionally a skilled engineer was required to implement designing by spending time and work and therefore there was such a problem that FIR filters with a desired characteristic cannot be designed easily.

Here, there known is a method of adjusting a filter band by inserting one or more zero values between respective taps (between respective filter coefficients) on a tapped delay line (see, for example, National Publication of International Patent Application No. 6-503450). In addition, there known is a method of realizing steep frequency characteristic by connecting a plurality of FIR filters in cascade connection (see, for example, Japanese Patent Laid-Open No. H5-243908). However, use of any of these methods can merely narrow the passband of a filter but it used to be unable to realize arbitrarily shaped frequency characteristic with a fewer number of taps.

### DISCLOSURE OF THE INVENTION

The present invention was implemented in order to solve such problem and an object thereof is to provide an FIR digital filter, which can realize a desired frequency characteristic with a small circuit size and with a high accuracy, and a designing method thereof.

In addition, an object of the present invention is to make an FIR digital filter having a desired frequency characteristic designable simply.

In order to solve the above described issues, in the present invention, for example, one or more FIR-type basic filters having a symmetric sequence of numbers having a predetermined characteristic as filter coefficients are arbitralily combined and connected arbitrarily in cascade connection. The filter coefficients are calculated and for the data of the calculated filter coefficients, the lower bits are cut off for rounding so as to reduce the bit count of filter coefficients.

Another mode of the present invention is designed to multiply the calculated filter coefficients by a predetermined amount for rounding the number after the decimal point to an integer.

According to the present invention configured as described above, it is possible to significantly reduce unnecessary filter coefficients by rounding the lower bits of the filter coefficients. Thereby, that is, only significantly small number of taps will be required for the digital filter to be designed and types of filter coefficients for the respective tap outputs will be required only to a significantly small extent. Accordingly, it is possible to significantly reduce the amount of circuit elements (in particular, multipliers) to reduce the circuit size.

In addition, since it is possible to significantly reduce the number of unnecessary filter coefficients by rounding, it is possible to make the conventional window multiplication unnecessary in order to reduce the number of filter coefficients. In the present invention, even if filter coefficients with a value smaller than a predetermined threshold value are cut off by rounding for reducing, a bit number, major filter coefficients of determining a frequency characteristic almost remains so as to hardly impart a bad effect to the frequency characteristic. In addition, since it is possible to design a digital filter without performing the window multiplication, no truncation error will occur to the frequency characteristic but it will become possible to improve the cut off characteristic to an extremely large extent so as to make available a filter characteristic with a phase characteristic being linear and excellent. That is, it is possible to realize a desired frequency characteristic of a digital filter with a high accuracy.

Moreover, since it is possible to design a digital filter having a desired filter characteristic only by such a simple operation that any basic filters are combined and connected in cascade connection and the like, even not skilled engineers can design a filter extremely easily.

In addition, according to another mode of the present invention, the number of the filter coefficients can be transformed into an integer and be simplified. Thereby, configuring a coefficient multiplier by a bit shift circuit instead of multiplier, it is possible to simplify the digital filter to be implemented further.

### BRIEF DESCRIPTION OF THE DRAWINGS

FIG. 1 is a table showing filter coefficients of a basic lowpass filter L4an;

FIG. 2 is a diagram showing a frequency characteristic of a basic lowpass filter L4a4;

FIG. 3 is a diagram showing a frequency-gain characteristic of a basic lowpass filter L4an;

FIG. 4 is a table showing filter coefficients of a basic lowpass filter Lan;

FIG. 5 is a diagram showing a frequency characteristic of a basic lowpass filter La4;

FIG. 6 is a diagram showing a frequency-gain characteristic of a basic lowpass filter Lan;

FIG. 7 is a table showing filter coefficients of a basic highpass filter H4sn;

FIG. 8 is a diagram showing a frequency characteristic of a basic highpass filter H4s4;

FIG. 9 is a diagram showing a frequency-gain characteristic of a basic highpass filter H4sn;

FIG. 10 is a table showing filter coefficients of a basic highpass filter Hsn;

FIG. 11 is a diagram showing a frequency characteristic of a basic highpass filter Hs4;

FIG. 12 is a diagram showing a frequency-gain characteristic of a basic highpass filter Hsn;

FIG. 13 is a table showing filter coefficients of a basic bandpass filter B4sn;

FIG. 14 is a diagram showing a frequency characteristic of a basic bandpass filter B4s4;

FIG. 15 is a diagram showing a frequency-gain characteristic of a basic bandpass filter B4sn;

FIG. 16 is a table showing filter coefficients of a basic bandpass filter Bsn;

FIG. 17 is a diagram showing a frequency characteristic of a basic bandpass filter Bs4;

FIG. 18 is a diagram showing a frequency-gain characteristic of a basic bandpass filter Bsn;

FIG. 19 is a diagram showing a frequency-gain characteristic with m being a parameter in a basic highpass filter Hmsn;

FIG. 20 is a diagram showing optimum values of a parameter n to a parameter m;

FIG. 21 is a diagram showing a relation between a parameter m and an optimum value of a parameter n thereto as well as a relation between a parameter m and a parameter x thereto;

FIG. 22 is a diagram showing an impulse response of a basic highpass filter Hmsn;

FIG. 23 is a diagram showing a frequency-gain characteristic of basic lowpass filters L4a4 and L4a4 (1);

FIG. 24 is a diagram for describing operation contents of filter coefficients in the case where basic filters are connected in cascade connection;

FIG. 25 is a diagram showing a frequency-gain characteristic of basic lowpass filters (L4a4)^{M};

FIG. 26 is a diagram showing a frequency-gain characteristic of basic highpass filters (H4s4)^{M};

FIG. 27 is a diagram schematically showing a method of designing a bandpass filter derived by connecting basic filters in cascade connection;

FIG. 28 is a diagram showing a specific designing example of a bandpass filter derived by connecting basic filters in cascade connection;

FIG. 29 is a diagram showing a specific designing example of a bandpass filter derived by connecting basic filters in cascade connection;

FIG. 30 is a diagram schematically showing means of narrowing the bandwidth with heterogeneous basic filters in cascade connection;

FIG. 31 is a diagram schematically showing means of widening the bandwidth with the homogeneous basic filters in cascade connection;

FIG. 32 is a diagram schematically showing means for fine-tuning the bandwidth;

FIG. 33 is a diagram subject to graphing filter coefficient values (those prior to rounding) actually calculated with a 16-bit operation accuracy;

FIG. 34 is a diagram showing a frequency characteristic of a digital filter prior to rounding filter coefficients;

FIG. 35 is a diagram showing filter coefficient values for 41 taps (46 stages being stage counts inclusive of zero values) left as a result of implementing 10-bits rounding to filter coefficients in FIG. 33 and coefficient values subject to transform them into integers;

FIG. 36 is a diagram showing a frequency-gain characteristic in the case where filter coefficients are calculated with a 16-bit operation accuracy and thereafter they are transformed into integers with 10-bits rounding;

FIG. 37 is a flow chart showing procedure of a method of designing a digital filter according to the second embodiment;

FIG. 38 is a diagram showing a frequency characteristic for describing a concept of a method of designing a digital filter according to the second embodiment;

FIG. 39 is a diagram showing a frequency-gain characteristic of an original bandpass filter and a diagram showing a frequency-gain characteristic derived in case of connecting one to three adjustment filters in cascade connection to this original bandpass filter;

FIG. 40 is a diagram for describing a principle of change in a frequency characteristic derived in case of connecting, in cascade connection, an adjustment filter according to the second embodiment;

FIG. 41 is a diagram showing a frequency characteristic derived in case of connecting, to an original bandpass filter, three stages of adjustment filters with α=1.5 in cascade connection and further connecting an adjustment filter with α=1 in cascade connection to the last stage;

FIG. 42 is a diagram showing a frequency-gain characteristic of an original lowpass filter and a diagram showing a frequency-gain characteristic derived in case of connecting one to five adjustment filters in cascade connection to this original lowpass filter;

FIG. 43 is a flow chart showing procedure of a method of designing a digital filter according to the third embodiment;

FIG. 44 is a flow chart showing procedure of a method of generating basic filters according to the third embodiment;

FIG. 45 is a diagram showing a frequency-gain characteristic of a basic filter according to the third embodiment;

FIG. 46 is a diagram showing a frequency-gain characteristic of a basic filter according to the third embodiment and a plurality of frequency shift filters generated therefrom;

FIG. 47 is a diagram showing an example of a frequency-gain characteristic of a digital filter generated with a filter designing method of the third embodiment;

FIG. 48 is a diagram showing a frequency-gain characteristic for describing cutout of a basic filter with a window filter;

FIG. 49 is a block diagram showing a configuration example of a designing apparatus of a digital filter according to the third embodiment;

FIG. 50 is a block diagram showing a configuration example of a digital filter according to the first embodiment;

FIG. 51 is a block diagram showing a configuration example of a digital filter according to the second embodiment; and

FIG. 52 is a block diagram showing a configuration example of a digital filter according to the third embodiment.

### BEST MODE FOR CARRYING OUT THE INVENTION

### First Embodiment

First embodiment of the present invention will be described below based on the drawings. In the present embodiment, several types of basic filters having a particular impulse response are defined to realize an FIR filter having a desired frequency characteristic in a form of connecting them in any cascade connection. A basic filter is generally categorized into three kinds of basic lowpass filters, basic highpass filters and basic bandpass filters (inclusive of a comb filter). These basic filters will be described below.

<Basic Lowpass Filter Lman (m and n are Variable with n Being a Natural Number)>

Filter coefficients of a basic lowpass filter Lman are derived by the moving average operation of bringing original data prior to operation and prior data prior to a predetermined amount of delay thereof into sequential addition with a sequence of numbers “−1, m, −1” as a starting point.

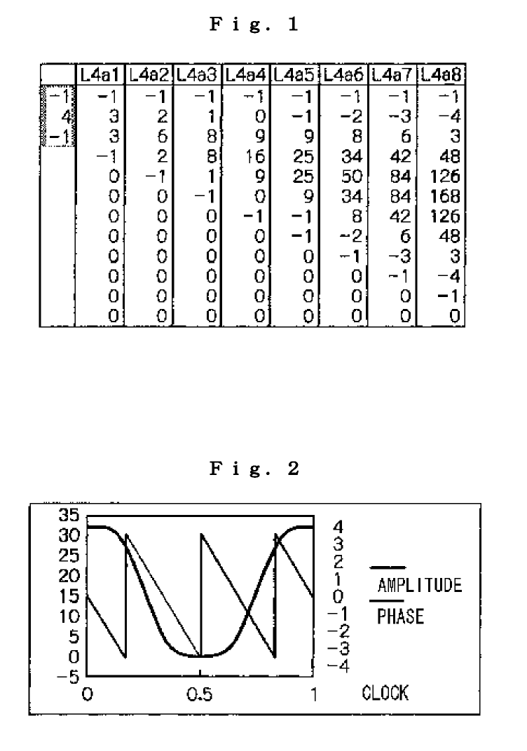

FIG. 1 is a diagram showing filter coefficients of a basic lowpass filter L4an (m=4). In FIG. 1, at the time of deriving j-th filter coefficient from the top in the n-th column above by the moving average operation, the original data refer to the j-th data from the top in the (n−1)-th in column. In addition, prior data refer to the (j−1)-th data from the top in (n−1)-th column.

For example, the first numeric value “−1” from the top of the basic lowpass filter L4a1 is derived by bringing an original data “−1” and the prior data “0” into addition and the second numeric value “3” is derived by bringing the original data “4” and the prior data “−1” into addition. In addition, the third numeric value “3” is derived by bringing an original data “−1” and the prior data “4” into addition and the fourth numeric value “−1” is derived by bringing an original data “0” and the prior data “−1” into addition.

In any filter coefficient of the basic lowpass filter L4an shown in FIG. 1, its sequence of numbers is symmetrical and has a characteristic that total value of numbers skipped by one in a sequence of numbers will become equal with the same positive or negative sign (for example, in case of basic lowpass filter L4a4, −1+9+9+(−1)=16, 0+16+0=16).

The sequence of numbers of the above described (−1, m, −1) is generated with the very first original sequence of numbers “−1, N” as a base. A basic unit filter with this sequence of numbers “−1, N” as filter coefficients has one to two units of taps (one unit in case of N=0 and two units in the other cases). Here, the value of N does not necessarily have to be an integer.

The basic unit filter with this sequence of numbers “−1, N” as filter coefficients is non-symmetrical, and therefore, in order to make it symmetrical, it is necessary to connect this in cascade connection in even number of stages for use. For example, in case of connecting two stages in cascade connection, an operation of convolution of the sequence of numbers “−1, N” will impart filter coefficients “−N, N²+1, −N”. Here, with (N²+1)/N=m, m being an integer, N=(m+(m²−4)^{1/2})/2 is derived.

As an example in FIG. 1, in case of m=4, N=2+√3 is derived. That is, coefficients of the basic unit filter will become “−1, 3.732” (here, up to three digits after the decimal points are indicated). In addition, filter coefficients in case of connecting two stages of this basic unit filters in cascade connection will become “−3.732, 14.928, −3.732”. This sequence of numbers configures a relation of −1:4:−1.

In case of using this sequence of numbers as filter coefficients actually, dividing each value of the sequence of numbers by 2N(=2*(2+√3)=7.464), the gain is standardized (normalized) to “1” so that amplitude in the case where the sequence of numbers of filter coefficients has undergone FFT transformation becomes “1”. That is, the sequence of numbers of filter coefficients for actual use will become “½, 2, −½”. This sequence of numbers for actual use is equivalent to the original sequence of numbers “−1, 4, −1” multiplied by z (z=1/(m−2)).

In case of using thus standardized sequence of numbers as filter coefficients, the filter coefficients of a basic lowpass filter Lman has a characteristic that any grand total in the sequence of numbers thereof will become “1” and the total value of numbers skipped by one in a sequence of numbers will become equal each other with the same positive or negative sign.

FIG. 2 is a diagram showing a frequency characteristic (a frequency-gain characteristic as well as a frequency-phase characteristic) of a basic lowpass filter L4a4 (in case of m=4, n=4) derived by bringing the sequence of numbers of filter coefficients into FFT transformation. Here, the gain is indicated by a linear scale, showing a standardized gain multiplied by 32. On the other hand, frequency is standardized with “1”.

As apparent from this FIG. 2, the frequency-gain characteristic is derived to be approximately flat in a pass range and be inclined gradually in a cutoff range. In addition, a frequency-phase characteristic is derived to be approximately linear. Thus, the basic lowpass filter L4a4 can derive a good frequency characteristic of lowpass filter without presence of overshoot and ringing.

FIG. 3 is a diagram showing a frequency-gain characteristic of a basic lowpass filter L4an with n being a parameter, where (a) indicates the gain by a linear scale and (b) indicates the gain by a logarithmic scale. According to this FIG. 3, as the value of n gets larger, inclination of the cutoff range will become apparently steeper. It can be said that this basic lowpass filter L4an is appropriate for use of comparatively steep frequency characteristic with n≧5 and is appropriate for use of comparatively moderate frequency characteristic with n<5.

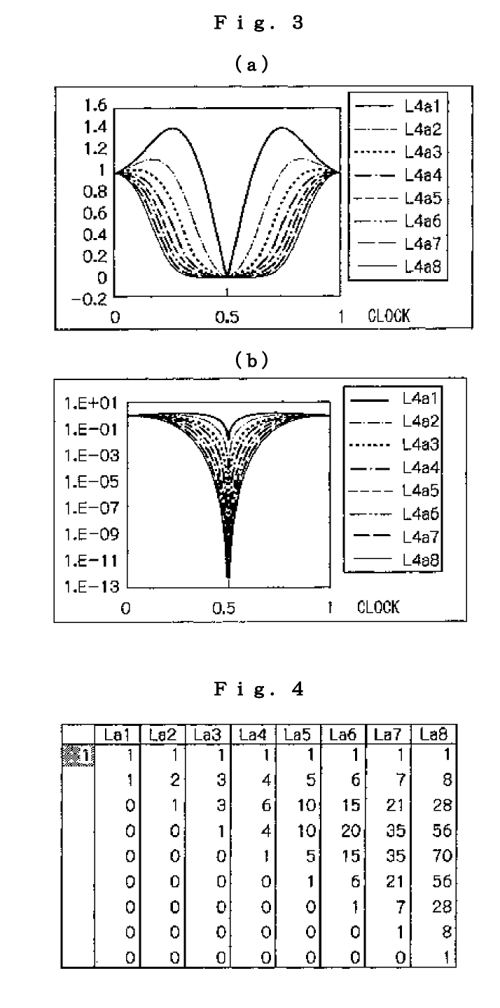

FIG. 4 is a table showing filter coefficients of a basic lowpass filter Lan in case of a sequence of numbers “−1, N” of a basic unit filter with N=0. In case of N=0, the filter coefficients at the time of connecting two stages of basic unit filters in cascade connection will become “0, 1, 0”. Accordingly, the filter coefficients of the basic lowpass filter Lan are derived by a moving average operation that sequentially adds an original data and the prior data with “1” as a starting point.

In any filter coefficients of the basic lowpass filter Lan shown in FIG. 4, its sequence of numbers is symmetrical and has a characteristic that total value of numbers skipped by one in a sequence of numbers will become equal with the same positive or negative sign (for example, in case of basic lowpass filter La4, 1+6+1=8, 4+4=8).

FIG. 5 is a diagram showing a frequency characteristic of a basic lowpass filter La4 derived by bringing the sequence of numbers of filter coefficients into FFT transformation. Here, the gain is indicated by a linear scale, showing a standardized gain multiplied by 16. On the other hand, frequency is standardized with “1”.

As apparent from this FIG. 5, the frequency-gain characteristic is derived to be approximately flat in a pass range, which will get narrower compared with that in FIG. 2, and be inclined gradually in a cutoff range. In addition, a frequency-phase characteristic is derived to be approximately linear. Thus, the basic lowpass filter La4 can also derive a good frequency characteristic of lowpass filter without presence of overshoot and ringing.

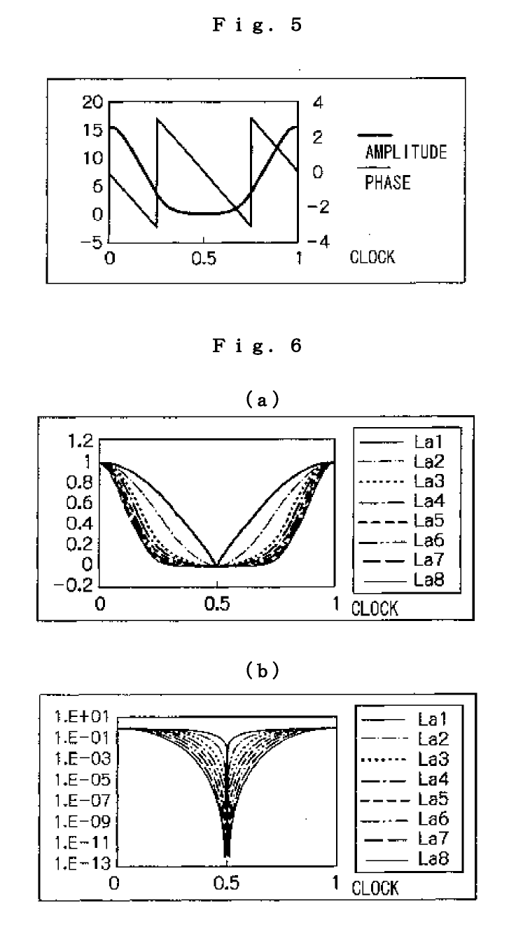

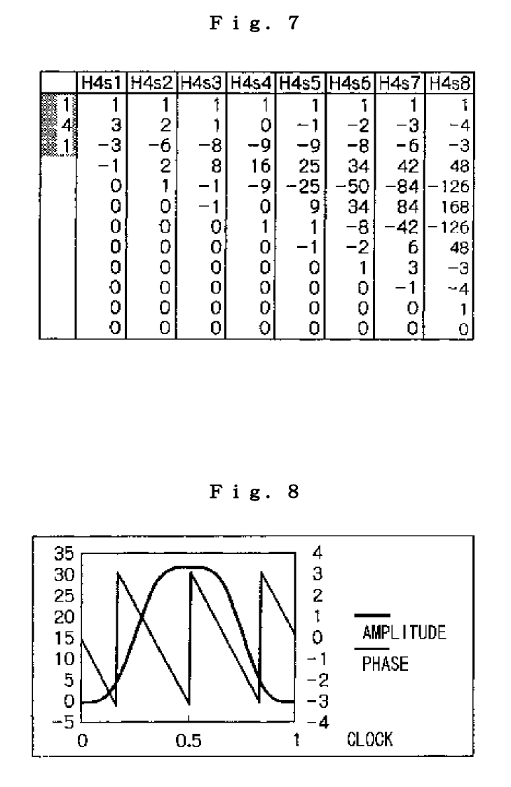

FIG. 6 is a diagram showing a frequency-gain characteristic of a basic lowpass filter Lan with n being a parameter, where (a) indicates the gain by a linear scale and (b) indicates the gain by a logarithmic scale. According to this FIG. 6, as the value of n gets larger, inclination of the cutoff range will become apparently steeper. It can be said that this basic lowpass filter Lan is appropriate for use of comparatively steep frequency characteristic with n≧5 and is appropriate for use of comparatively moderate frequency characteristic with n<5.

<Basic Highpass Filter Hmsn (m and n are Variable with n Being a Natural Number)>

Filter coefficients of a basic highpass filter Hmsn are derived by the moving average operation of sequentially subtracting, from original data prior to operation, prior data prior to a predetermined amount of delay thereof with a sequence of numbers “1, m, 1” as a starting point.

FIG. 7 is a diagram showing filter coefficients of a basic highpass filter H4sn (m=4). In FIG. 7, at the time of deriving j-th filter coefficients from the top in the n-th column above by the moving average operation, the original data refer to the j-th data from the top in the (n−1)-th in column. In addition, prior data refer to the (j−1)-th data from the top in (n−1)-th column.

For example, the first numeric value “1” from the top of the basic highpass filter H4s1 is derived by subtracting, from an original data “1”, the prior data “0” and the second numeric value “3” is derived by subtracting, from the original data “4”, the prior data “1”. In addition, the third numeric value “−3” is derived by subtracting, from original data “1”, the prior data “4” and the fourth numeric value “−1” is derived by subtracting, from original data “0”, the prior data “1”.

In any filter coefficients of the basic highpass filter H4sn shown in FIG. 7, with n being even numbers, its sequence of numbers is symmetrical and has a characteristic that total value of numbers skipped by one in a sequence of numbers will become equal with the positive or negative opposite sign (for example, in case of basic highpass filter H4s4, 1+(−9)+(−9)+1=−16, 0+16+0=16). With n being odd numbers, its sequence of numbers is symmetrical in the absolute value and the first half of the sequence of numbers will have positive or negative sign opposite from that of the latter half of the sequence of numbers. In addition, there is a characteristic that total value of numbers skipped by one in a sequence of numbers will become equal each other with the opposite positive or negative sign.

The sequence of numbers of the above described (1, m, 1) is generated with the very first original sequence of numbers “1, N” as a base. A basic unit filter with this sequence of numbers “1, N” as filter coefficients has one to two units of taps (one unit in case of N=0 and two units in the other cases). Here, the value of N does not necessarily have to be an integer.

The basic unit filter with this sequence of numbers “1, N” as filter coefficients is non-symmetrical, and therefore, in order to make it symmetrical, it is necessary to connect this in cascade connection in even number of stages for use. For example, in case of connecting two stages in cascade connection, an operation of convolution of the sequence of numbers “1, N” will impart filter coefficients “N, N²+1, N”. Here, with (N²+1)/N=m, m being an integer, N=(m+(m²−4)^{1/2})/2 is derived.

As an example in FIG. 7, in case of m=4, N=2+√3 is derived. That is, coefficients of the basic unit filter will become “1, 3.732” (here, up to three digits after the decimal points are indicated). In addition, filter coefficients in case of connecting two stages of this basic unit filters in cascade connection will become “3.732, 14.928, 3.732”. This sequence of numbers configures a relation of 1:4:1.

In case of using this sequence of numbers as filter coefficients actually, dividing each value of the sequence of numbers by 2N(=2*(2+√3)=7.464), the gain is standardized to “1” so that amplitude in the case where the sequence of numbers of filter coefficients has undergone FFT transformation becomes “1”. That is, the sequence of numbers of filter coefficients for actual use will become “½, 2, ½”. This sequence of numbers “½, 2, ½” for actual use is also equivalent to the original sequence of numbers “1, 4, 1” multiplied by z (z=1/(m−2)).

In case of using thus standardized sequence of numbers as filter coefficients, the filter coefficients of a basic highpass filter Hmsn have a characteristic that any grand total in the sequence of numbers thereof will become “0” and the total value of numbers skipped by one in a sequence of numbers will become equal each other with the positive or negative opposite sign.

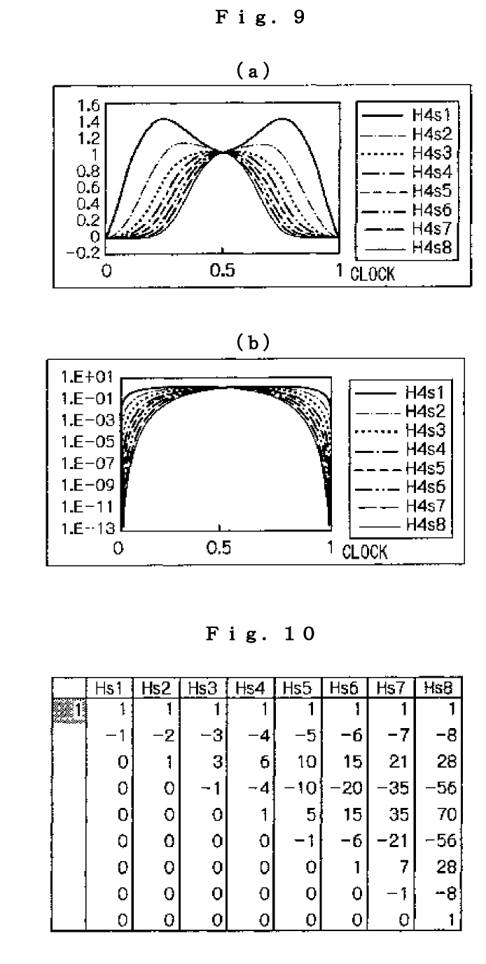

FIG. 8 is a diagram showing a frequency characteristic of a basic highpass filter H4s4 (in case of m=4, n=4) derived by bringing the sequence of numbers of filter coefficients into FFT transformation. Here, the gain is indicated by a linear scale, showing a standardized gain multiplied by 32. On the other hand, frequency is standardized with As apparent from this FIG. 8, the frequency-gain characteristic is derived to be approximately flat in a pass range and be inclined gradually in a cutoff range. In addition, a frequency-phase characteristic is derived to be approximately linear. Thus, the basic highpass filter H4s4 can derive a good frequency characteristic of highpass filter without presence of overshoot and ringing.

FIG. 9 is a diagram showing a frequency-gain characteristic of a basic highpass filter H4sn with n being a parameter, where (a) indicates the gain by a linear scale and (b) indicates the gain by a logarithmic scale. According to this FIG. 9, as the value of n gets larger, inclination of the cutoff range will become apparently steeper. It can be said that this basic highpass filter H4sn is appropriate for use of comparatively steep frequency characteristic with n≧5 and is appropriate for use of comparatively moderate frequency characteristic with n<5.

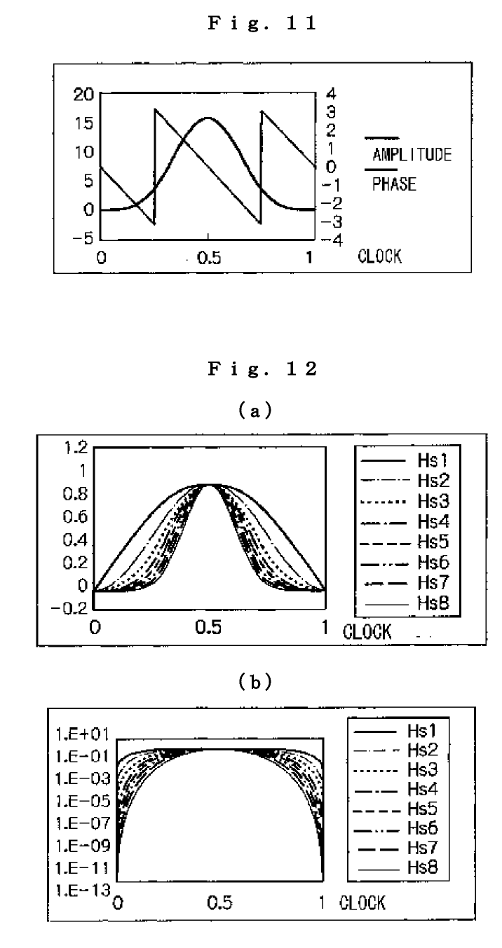

FIG. 10 is a table showing filter coefficients of a basic highpass filter Hsn in case of a sequence of numbers “1, N” of a basic unit filter with N=0. In case of N=0, the filter coefficients at the time of connecting two stages of basic unit filters in cascade connection will become “0, 1, 0”. Accordingly, the filter coefficients of the basic highpass filter Hsn are derived by a moving average operation that sequentially subtracts, from an original data, the prior data with “1” as a starting point.

In any filter coefficients of the basic highpass filter Hsn shown in FIG. 10, with n being even numbers, its sequence of numbers is symmetrical and has a characteristic that total value of numbers skipped by one in a sequence of numbers will become equal with the positive or negative opposite sign (for example, in case of basic highpass filter Hs4, 1+6+1=8, −4+(−4)=−8). With n being odd numbers, its sequence of numbers is symmetrical in the absolute value and the first half of the sequence of numbers will have positive or negative sign opposite from that of the latter half of the sequence of numbers. In addition, there is a characteristic that total value of numbers skipped by one in a sequence of numbers will become equal each other with the positive or negative opposite sign.

FIG. 11 is a diagram showing a frequency characteristic of a basic highpass filter Hs4 derived by bringing the sequence of numbers of filter coefficients into FFT transformation. Here, the gain is indicated by a linear scale, showing a standardized gain multiplied by 16. On the other hand, frequency is standardized with As apparent from this FIG. 11, the frequency-gain characteristic is derived to be approximately flat in a pass range, which will get narrower compared with that in FIG. 8, and be inclined gradually in a cutoff range. In addition, a frequency-phase characteristic is derived to be approximately linear. Thus, the basic highpass filter Hs4 can also derive a good frequency characteristic of lowpass filter without presence of overshoot and ringing.

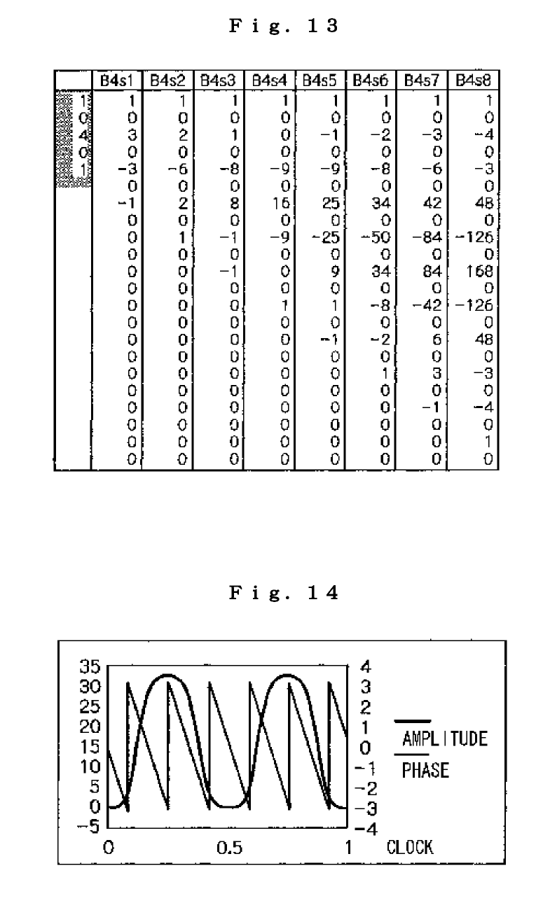

FIG. 12 is a diagram showing a frequency-gain characteristic of a basic highpass filter Hsn with n being a parameter, where (a) indicates the gain by a linear scale and (b) indicates the gain by a logarithmic scale. According to this FIG. 12, as the value of n gets larger, inclination of the cutoff range will become apparently steeper. It can be said that this basic highpass filter Hsn is appropriate for use of comparatively steep frequency characteristic with n≧5 and is appropriate for use of comparatively moderate frequency characteristic with n<5.

<Basic Bandpass Filter Bmsn (m and n are Variable with n Being a Natural Number)>

Filter coefficients of a basic bandpass filter Bmsn are derived by the moving average operation of sequentially subtracting, from original data prior to operation, prior data twice prior to a predetermined amount of delay thereof with a sequence of numbers “1, 0, m, 0, 1” as a starting point.

FIG. 13 is a diagram showing filter coefficients of a basic bandpass filter B4sn (in case of m=4). In FIG. 13, at the time of deriving j-th filter coefficients from the top in the n-th column above by the moving average operation, the original data refer to the j-th data from the top in the (n−1)-th in column. In addition, prior data refer to the (j−2)-th data from the top in (n−1)-th column.

For example, the first numeric value “1” from the top of the basic bandpass filter B4s1 is derived by subtracting, from an original data “1”, the prior data “0” and the third numeric value “3” is derived by subtracting, from the original data “4”, the prior data “1”. In addition, the fifth numeric value “−3” is derived by subtracting, from original data “1”, the prior data “4” and the seventh numeric value “−1” is derived by subtracting, from original data “0”, the prior data “1”.

Upon the basic bandpass filter B4sn shown in FIG. 13, in any filter coefficients with n being even numbers, its sequence of numbers is symmetrical and has a characteristic that total value of numbers skipped by three in a sequence of numbers will become equal each other with the positive or negative opposite sign (for example, in case of basic bandpass filter B4s4, 1+(−9)+(−9)+1=−16, 0+16+0=16). With n being odd numbers, its sequence of numbers is symmetrical in the absolute value and the first half of the sequence of numbers will have positive or negative sign opposite from that of the latter half of the sequence of numbers. In addition, there is a characteristic that total value of numbers skipped by three in a sequence of numbers will become equal each other with the opposite positive or negative sign.

The sequence of numbers of the above described (1, 0, m, 0, 1) is generated with the very first original sequence of numbers “1, 0, N” as a base. A basic unit filter with this sequence of numbers “1, 0, N” as filter coefficients has one to two units of taps (one unit in case of N=0 and two units in the other cases). Here, the value of N does not necessarily have to be an integer.

The basic unit filter with this sequence of numbers “1, 0, N” as filter coefficients is non-symmetrical, and therefore, in order to make it symmetrical, it is necessary to connect this in cascade connection in even number of stages for use. For example, in case of connecting two stages in cascade connection, an operation of convolution of the sequence of numbers “1, 0, N” will impart filter coefficients “N, 0, N²+1, 0, N”. Here, with (N²+1)/N=m, m being an integer, N=(m+(m²−4)^{1/2})/2 is derived.

As an example in FIG. 13, in case of m=4, N=2+√3 is derived. That is, coefficients of the basic unit filter will become “1, 0, 3.732” (here, up to three digits after the decimal points are indicated). In addition, filter coefficients in case of connecting two stages of this basic unit filters in cascade connection will become “3.732, 0, 14.928, 0, 3.732”. This sequence of numbers configures a relation of 1:0:4:0:1.

In case of using this sequence of numbers as filter coefficients actually, dividing each value of the sequence of numbers by 2N(=2*(2+√3)=7.464), the gain is standardized to “1” so that amplitude in the case where the sequence of numbers of filter coefficients has undergone FFT transformation becomes “1”. That is, the sequence of numbers of filter coefficients for actual use will become “½, 0, 2, 0, ½”. This sequence of numbers “½, 0, 2, 0, ½” for actual use is also equivalent to the original sequence of numbers “1, 0, 4, 0, 1” multiplied by z (z=1/(m−2)).

In case of using thus standardized sequence of numbers as filter coefficients, the filter coefficients of a basic bandpass filter Bmsn have a characteristic that any grand total in the sequence of numbers thereof will become “0” and the total value of numbers skipped by three in a sequence of numbers will become equal each other with the positive or negative opposite sign.

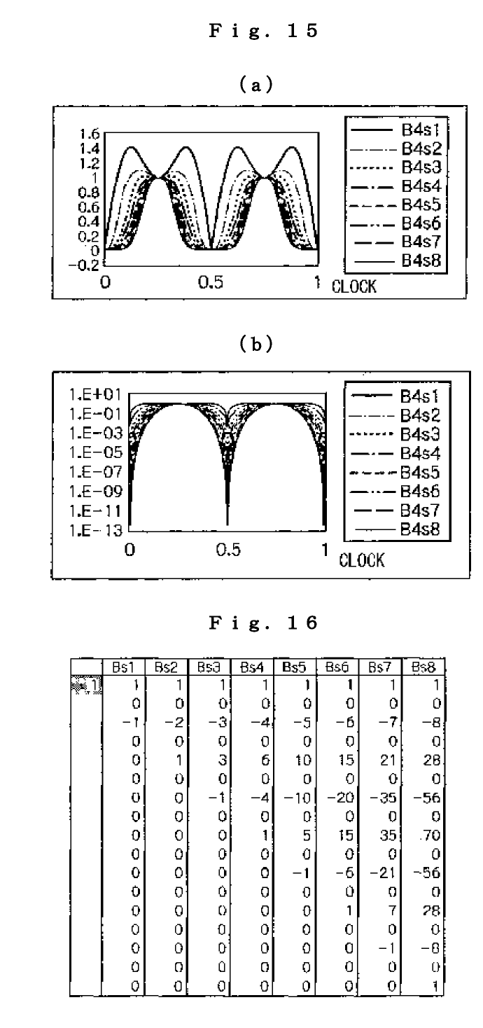

FIG. 14 is a diagram showing a frequency characteristic of a basic bandpass filter B4s4 (in case of m=4, n=4) derived by bringing the sequence of numbers of filter coefficients into FFT transformation. Here, the gain is indicated by a linear scale, showing a standardized gain multiplied by 32. On the other hand, frequency is standardized with “1”.

As apparent from this FIG. 14, the frequency-gain characteristic is derived to be approximately flat in a pass range and be inclined gradually in a cutoff range. In addition, a frequency-phase characteristic is derived to be approximately linear. Thus, the basic bandpass filter B4s4 can derive a good frequency characteristic of bandpass filter without presence of overshoot and ringing.

FIG. 15 is a diagram showing a frequency-gain characteristic of a basic bandpass filter B4sn with n being a parameter, where (a) indicates the gain by a linear scale and (b) indicates the gain by a logarithmic scale. According to this FIG. 15, as the value of n gets larger, inclination of the cutoff range will become apparently steeper. It can be said that this basic bandpass filter B4sn is appropriate for use of comparatively steep frequency characteristic with n≧5 and is appropriate for use of comparatively moderate frequency characteristic with n<5.

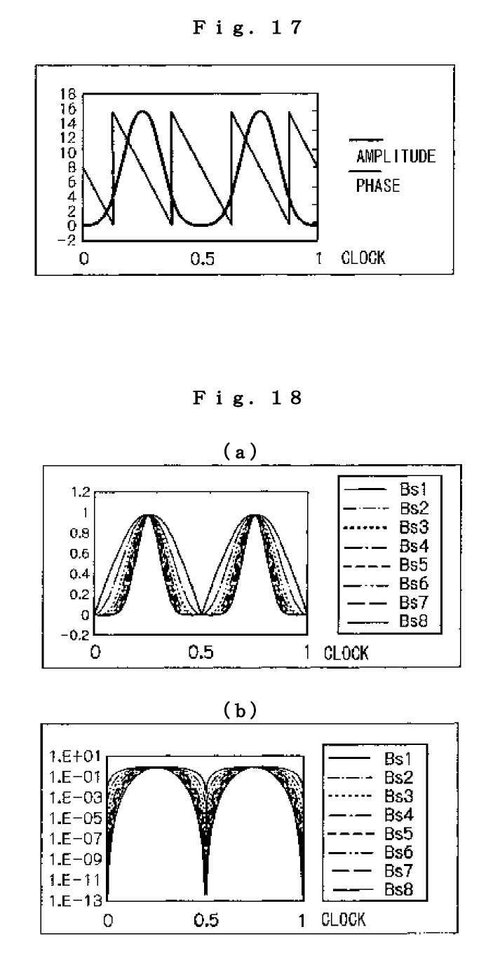

FIG. 16 is a table showing filter coefficients of a basic bandpass filter Bsn in case of a sequence of numbers “1, 0, N” of a basic unit filter with N=0. In case of N=0, the filter coefficients at the time of connecting two stages of basic unit filters in cascade connection will become “0, 0, 1, 0, 0”. Accordingly, the filter coefficients of the basic bandpass filter Bsn are derived by a moving average operation that sequentially subtracts, from an original data, the twice prior data with “1” as a starting point.

Upon the basic bandpass filter Bsn shown in FIG. 16, in any filter coefficients with n being even numbers, its sequence of numbers is symmetrical and has a characteristic that total value of numbers skipped by three in a sequence of numbers will become equal each other with the positive or negative opposite sign (for example, in case of basic bandpass filter Bs4, 1+6+1=8, −4+(−4)=−8) With n being odd numbers, its sequence of numbers is symmetrical in the absolute value and the first half of the sequence of numbers will have positive or negative sign opposite from that of the latter half of the sequence of numbers. In addition, there is a characteristic that total value of numbers skipped by three in a sequence of numbers will become equal each other with the positive or negative opposite sign.

FIG. 17 is a diagram showing a frequency characteristic of a basic bandpass filter Bs4 derived by bringing the sequence of numbers of filter coefficients into FFT transformation. Here, the gain is indicated by a linear scale, showing a standardized gain multiplied by 16. On the other hand, frequency is standardized with As apparent from this FIG. 17, the frequency-gain characteristic is derived to be approximately flat in a pass range, which will get narrower compared with that in FIG. 14, and be inclined gradually in a cutoff range. In addition, a frequency-phase characteristic is derived to be approximately linear. Thus, the basic bandpass filter Bs4 can also derive a good frequency characteristic of bandpass filter without presence of overshoot and ringing.

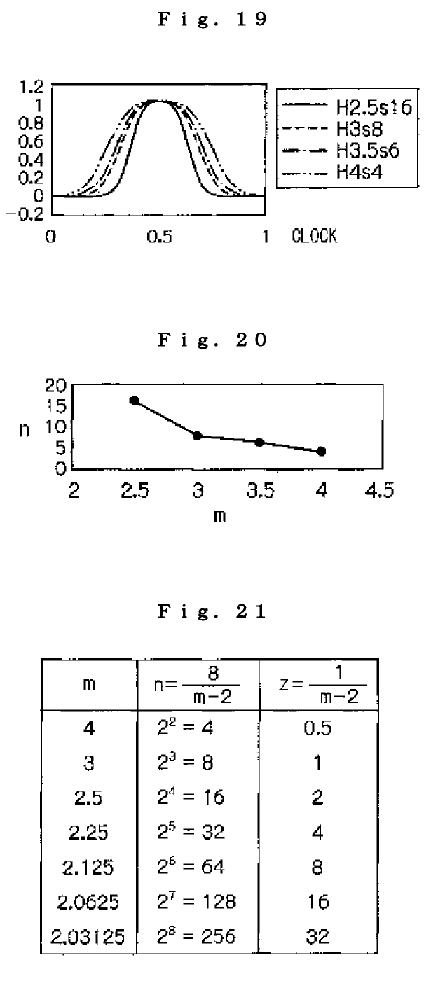

FIG. 18 is a diagram showing a frequency-gain characteristic of a basic bandpass filter Bsn with n being a parameter, where (a) indicates the gain by a linear scale and (b) indicates the gain by a logarithmic scale. According to this FIG. 18, as the value of n gets larger, inclination of the cutoff range will become apparently steeper. It can be said that this basic bandpass filter Bsn is appropriate for use of comparatively steep frequency characteristic with n≧5 and is appropriate for use of comparatively moderate frequency characteristic with n<5.

Here, so far, examples of performing moving average operation with “1” as a starting point have been described with reference to FIG. 4, FIG. 10 and FIG. 16, but “−1” may be adopted as the starting point. In case of adopting “−1” as the starting point, the phase characteristic shifts only by π but the frequency characteristic is the same and gives rise to no change.

<Influence of Parameter Values m and n on Characteristics>

At first, influence subject to changes in the stage count n of a moving average operation will be described. For example, as shown in FIG. 3, in a basic lowpass filter Lman, when the value of n is caused to get bigger, inclination in a cutoff range gets steeper to narrow the bandwidth of the pass range. In addition, when the value of n is small, the top part of the frequency characteristic rises in both ends. As the value of n gets larger, the top part approaches a flat state gradually and will get completely flattened with n=4. With the value of n getting larger than that, both ends of the top part will now get lower than the central value. Such tendency is likewise applicable to the basic highpass filter Hmsn and the basic bandpass filter Bmsn as well (see FIG. 9 and FIG. 15).

On the other hand, with regard to the basic lowpass filter Lan, the basic highpass filter Hsn and the basic bandpass filter Bsn configured with the coefficient value of the basic unit filter being N=0, in any case with regard to the value of n, both ends of the top parts will get lower than the central value as shown in FIG. 6, FIG. 12 and FIG. 18. As in cases of the basic lowpass filter Lman, the basic highpass filter Hmsn and the basic bandpass filter Bmsn with N≠0, when the value of n gets larger, the inclination of a cutoff range will likewise get steeper and the bandwidth of a pass range will get narrower.

Next, influence subject to changes in the value of m will be described. FIG. 19 is a diagram showing a frequency-gain characteristic with m being a parameter in the basic highpass filter Hmsn. According to this FIG. 19, when the value of m is caused to get smaller, it is apparent that the inclination of the cutoff range will get steeper and the bandwidth of the pass range will get narrower. Here, depiction is omitted but the basic lowpass filter Lman and the basic bandpass filter Bmsn can be described likewise.

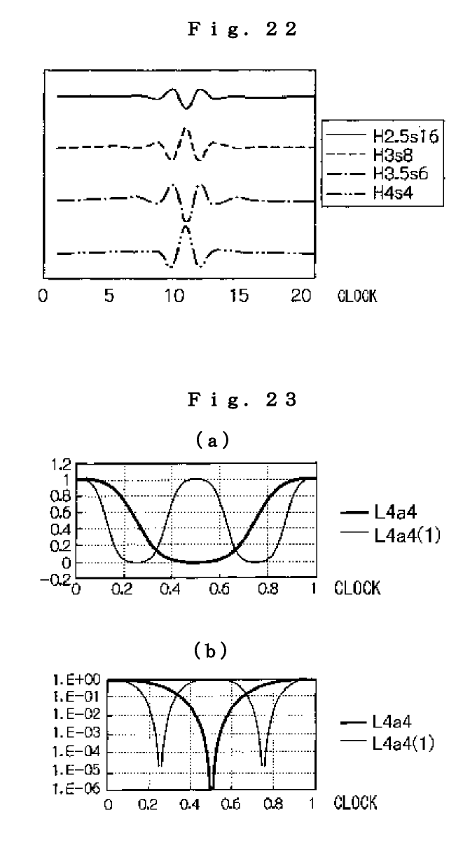

This FIG. 19 concurrently shows optimum values (the value of n making the top part of a frequency characteristic flat) of the parameter n for the parameter m. That is, with m=4, the optimum value is n=4; with m=3.5, the optimum value is n=6; with m=3, the optimum value is n=8; and with m=2.5, the optimum value is n=16. This is graphed in a comprehensible fashion in FIG. 20. As apparent from this FIG. 20, the optimum value of the parameter n for the parameter m will get larger as the value of m gets smaller.

This will be described in detail further with reference to FIG. 21. FIG. 21 is a diagram showing relation between the parameter m and the parameter n for it in the form of a table. Here, FIG. 21 concurrently shows relation between the parameter m and the parameter z as well.

As described above, the optimum value of the parameter n for the parameter m gets larger as the value of m gets smaller. Here, with m=2, the filter characteristic will change significantly and a good frequency characteristic will become underivable. To put it the other way around, under the condition of m>2, without increasing the amount of delay to be inserted between the taps, a good filter characteristic with narrow bandwidth in a pass range can be derived. On the other hand, as the value of the parameter m gets larger, the optimum value of the parameter n gets smaller, that is, m=10 imparts n=1. That is, with m=10, one stage as the stage count of a moving average operation will do. According hereto, the parameter m is preferably used under the condition of 2<m≦10.

In addition, the frequency characteristic can be adjusted as in FIG. 3, FIG. 9 and FIG. 15 by using any value selected within a certain range containing the optimum values as the center shown in FIG. 21.

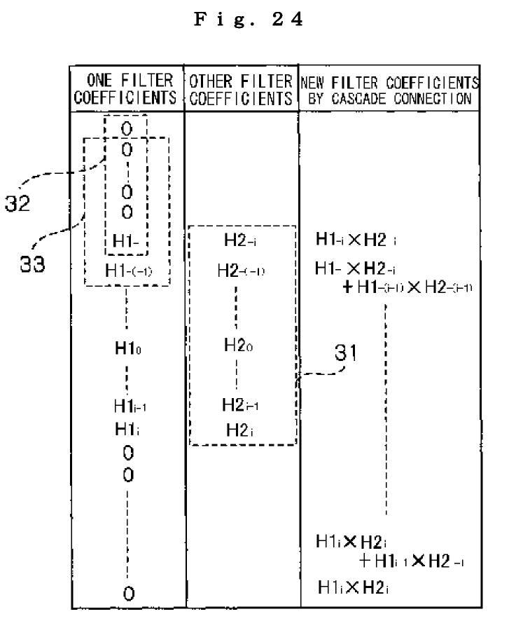

FIG. 22 is a diagram showing the impulse response of four types of basic highpass filter Hmsn shown in FIG. 19. The impulse response having waveforms as shown in this FIG. 22 is a function imparting a finite value other than “0” only when the sample position along the horizontal axis is present within a constant range and deriving “0” all for the other range, that is, a function converging the value into “0” in a predetermined sample position.

Thus, the case where the function will derive a finite value other than “0” in a local range and the value thereof will become “0” in the other range is called “finite base”. Here, depiction is omitted but the basic highpass filter Hsn, the basic lowpass filter Lman as well as Lan and the basic bandpass filter Bmsn as well as Bsn will likewise derive an impulse response forming a finite base.

In the impulse response of such a finite base, only data within a local range having finite value other than “0” are meaningful. Data beside this range are not necessarily ignored in spite that they should be considered essentially nor have to be considered theoretically and therefore do not give rise to any truncation error. Accordingly, using a sequence of numbers shown in FIG. 1, FIG. 4, FIG. 7, FIG. 10, FIG. 13 and FIG. 16 as filter coefficients, there is no need to truncate a coefficient by window multiplication but a good filter characteristic can be derived.

<Adjustment of Zero Value Between Filter Coefficients>

Changing the zero value between respective sequences of numbers (equivalent to the amount of delay between respective taps) configuring filter coefficients of basic filters, it is possible to adjust the bandwidth in pass ranges of basic filters. That is, for the above described basic lowpass filter Lman as well as Lan, basic highpass filter Hmsn as well as Hsn and basic bandpass filter Bmsn as well as Bsn, the amount of delay between respective taps was one clock portion, and if this is (k+1) clock portion (k units of “0” are inserted between the respective filter coefficients), the frequency axis of a frequency-gain characteristic thereof (cycle in the frequency direction) will become 1/(k+1) so that the bandwidth of the pass range will get narrow.

The case where k units of “0” are inserted between the respective filter coefficients in the basic lowpass filter Lman, for example, will be indicated below as Lman (k). Here, in case of k=0, (0) will be omitted from indication.

FIG. 23 is a diagram showing a frequency-gain characteristic of a basic lowpass filter L4a4 as well as a basic lowpass filter L4a4 (1) generated by inserting “0” individually between respective filter coefficients thereof, where (a) indicates the gain by a linear scale and (b) indicates the gain by a logarithmic scale. As apparent from this FIG. 23, taking k units of “0” inserted between the filter coefficients, the frequency axis of a frequency-gain characteristic thereof (cycle in the frequency direction) will become 1/(k+1) so as to make it possible to narrow the bandwidth of the pass range.

<Cascade Connection of Homogeneous Basic Filters>

Connecting the homogeneous basic filters in cascade connection, coefficients of the respective basic filters undergo multiplication and addition each other so as to create new filter coefficients. In the case where the number of cascade connection of the basic lowpass filter Lman, for example, is M, this will be described below as (Lman)^{M}.

Here, contents of an operation of filter coefficients in case of connecting the basic filters in cascade connection will be described. FIG. 24 is a diagram for describing the contents of an operation of filter coefficients derived by cascade connection. As shown in this FIG. 24, in case of connecting two basic filters in cascade connection, a new sequence of numbers of filter coefficients is derived by performing an operation of convolution on (2i+1) units (2i+1 describes the unit count of the whole sequence of numbers configuring filter coefficients of one party) of sequence of numbers {H1₋ᵢ, H1₋₍ᵢ₋₁₎, H1₋₍ᵢ₋₂₎, . . . , H1₋₁, H1₀, H1₁, . . . , H1ᵢ₋₂, H1ᵢ₋₁, H1ᵢ} configuring filter coefficients of one party and (2i+1) units of sequence of numbers {H2₋ᵢ, H2₋₍ᵢ₋₁₎, H2₋₍ᵢ₋₂₎, . . . , H2₋₁, H2₀, H2₁, . . . , H2ᵢ₋₂, H2_{i'1}, H2ᵢ} configuring filter coefficients of the other party.

Upon this operation of convolution, multiplication and addition are applied to the whole sequence of numbers of {H2₋ᵢ, H2₋₍ᵢ₋₁₎, H2₋₍ᵢ₋₂₎, . . . , H2₋₁, H2₀, H2₁, . . . , H2ᵢ₋₂, H2ᵢ₋₁, H2ᵢ} on the filter coefficients of the other party always in a fixed fashion. On the other hand, as for filter coefficients of the other party, the operation of convolution is applied to (2i+1) units of sequence of numbers inclusive of 0 value in the assumption that a sequence of 0 is present before and after the sequence of numbers of {H1₋ᵢ, H1₋₍ᵢ₋₁₎, H1₋₍ᵢ₋₂₎, . . . , H1₋₁, H1₀, H1₁, . . . , H1ᵢ₋₂, H1ᵢ₋₁, H1ᵢ}. At this time, when a p-th numeric value of the new filter coefficients is derived, multiplication and addition is applied to (2i+1) units of sequence of numbers prior thereto inclusive of the p-th numeric value of filter coefficients of the other party.

For example, at the time of deriving the first numeric value of the new filter coefficients, an operation of totaling the corresponding multiplied factors of the arrangement is applied to the whole sequence of numbers {H2₋ᵢ, H2₋₍ᵢ₋₁₎, H2₋₍ᵢ₋₂₎, . . . , H2₋₁, H2₀, H2₁, . . . , H2ᵢ₋₂, H2ᵢ₋₁, H2ᵢ} (an arrangement enclosed by dotted lines indicated by the reference numeral 31) of filter coefficients of the other party and (2i+1) units of sequence of numbers {0, 0, . . . , 0, H1₋ᵢ} (an arrangement enclosed by dotted lines indicated by the reference numeral 32) prior thereto inclusive of the first numeric value of filter coefficients of one party. That is, the operation in this case will result in (H1₋ᵢ×H2₋ᵢ).

In addition, at the time of deriving the second numeric value of the new filter coefficients, an operation of totaling the corresponding multiplied factors of the arrangement is applied to the whole sequence of numbers {H2₋ᵢ, H2₋₍ᵢ₋₁₎, H2₋₍ᵢ₋₂₎, . . . , H2₋₁, H2₀, H2₁, . . . , H2ᵢ₋₂, H2ᵢ₋₁, H2ᵢ} (an arrangement enclosed by dotted lines indicated by the reference numeral 31) of filter coefficients of the other party and (2i+1) units of sequence of numbers {0, 0, . . . , 0, H1₋ᵢ, H1₋₍ᵢ₋₁₎} (an arrangement enclosed by dotted lines indicated by the reference numeral 33) prior thereto inclusive of the second numeric value of filter coefficients of one party. That is, the operation in this case will result in (H1₋ᵢ×H2₋ᵢ+H1₋₍ᵢ₋₁₎×H2₋₍ᵢ₋₁₎). (2×(2i+1)−1) units of sequence of numbers configuring new filter coefficients will be likewise derived below.

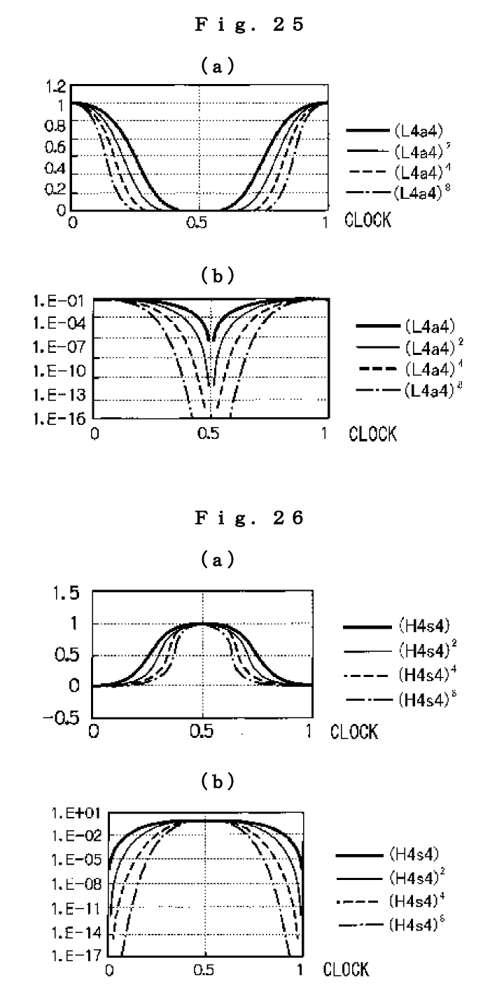

FIG. 25 is a diagram showing a frequency-gain characteristic of basic lowpass filters L4a4, (L4a4)², (L4a4)⁴ and (L4a4)⁸, where (a) indicates the gain by a linear scale and (b) indicates the gain by a logarithmic scale.

In case of only one unit of the basic lowpass filter L4a4, the clock of the position with amplitude to become 0.5 is 0.25. In contrast, when the number of M of the cascade connection becomes abundant, the pass bandwidth of a filter will get narrow. For example, in case of M=8, the clock at the position with the amplitude to become 0.5 will become 0.125.

As apparent from the above described FIG. 25, the basic lowpass filter L4a4 has a characteristic that the inclination of the cutoff frequency portion in the frequency characteristic is steep. In addition, on the frequency-gain characteristic of the basic lowpass filter (L4a4)^{M}, as the cascade connection count M gets abundant, the pass bandwidth gets narrower and derives a characteristic to drop extremely deeply and straight also in a low frequency range.

FIG. 26 is a diagram showing a frequency-gain characteristic of basic highpass filters H4s4, (H4s4)², (H4s4)⁴ and (H4s4)⁸, where (a) indicates the gain by a linear scale and (b) indicates the gain by a logarithmic scale. In case of only one unit of the basic highpass filter H4s4, the clock of the position with amplitude to become 0.5 is 0.25. In contrast, when the number of M of the cascade connection become abundant, the pass bandwidth of a filter will get narrow. For example, in case of M=8, the clock at the position with the amplitude to become 0.5 will become 0.375.

As apparent from the above described FIG. 26, the basic highpass filter H4s4 has a characteristic that the inclination of the cutoff frequency portion in the frequency characteristic is steep. In addition, on the frequency-gain characteristic of the basic highpass filter (H4s4)^{M}, as the number of M of the cascade connection the gets abundant, the pass bandwidth gets narrower and derives a characteristic to drop extremely deeply and straight also in a high frequency range.

<Cascade Connection of Heterogeneous Basic Filters>

Also in case of connecting heterogeneous basic filters in cascade connection, coefficients of the respective basic filters undergo multiplication and addition each other with an operation of convolution so as to create new filter coefficients. In this case, combining the heterogeneous basic filters arbitrarily, characteristics of the respective basic filters cancel each other to take out a desired frequency band. Thereby a lowpass filter, a highpass filter, a bandpass filter, a band elimination filter, a comb filter and the like with a desired characteristic can be designed easily.

An example of combining the above described basic lowpass filter L4a4 (k) and basic highpass filter H4s4 (k) to design a bandpass filter with a desired frequency band being pass band, for example, will be described.

When either the center frequency Fc of a bandpass filter or the sampling frequency Fs of a signal can be freely determined, optimization of conditions for taking out frequency can simplify configuration of the filter further. Now, suppose that the relation between the center frequency Fc of a bandpass filter and the sampling frequency Fs of a signal is
Fs=Fc*(4+2q) (q=0, 1, 2, . . . )

In this case, Fc=450 KHz imparts Fs=1.8 MHz, 2.7 MHz, 3.6 MHz, . . . In case of such a setting, a bandpass filter can be designed only by connecting a basic highpass filter H4s4(5+3 q) and a basic lowpass filter L4a4(3+2 q) in cascade connection. Both of these basic highpass filter H4s4 (5+3 q) and basic lowpass filter L4a4 (3+2 q) have a pass range with the center frequency Fc to become 450 KHz.

For example, in case of q=0 (Fs=4 Fc), a bandpass filter can be designed by connecting a basic highpass filter H4s4(5) and a basic lowpass filter L4a4 (3). In addition, in case of q=1 (Fs=6 Fc), a bandpass filter can be designed by connecting basic highpass filter H4s4(8) and a basic lowpass filter L4a4(5) in cascade connection.

FIG. 27 is a diagram schematically showing a method of designing the above described bandpass filter, where (a) indicates the case of q=0 and (b) indicates the case of q=1. For example, in FIG. 27 (a), connecting a basic highpass filter H4s4 (5) and a basic lowpass filter L4a4 (3) in cascade connection, only a mutually overlapped portion in the respective pass range #1 and #2 can be taken out as a pass range #3.

Also in FIG. 27(b), likewise connecting a basic highpass filter H4s4 (8) and a basic lowpass filter L4a4 (5) in cascade connection, only a mutually overlapped portion in the respective pass range #1 and #2 can be taken out as a pass range #3. In case of q>0, since a pass range appears beside the central frequency Fc of the demanded bandpass filter, this is extracted by a lowpass filter (LPF1)#4.

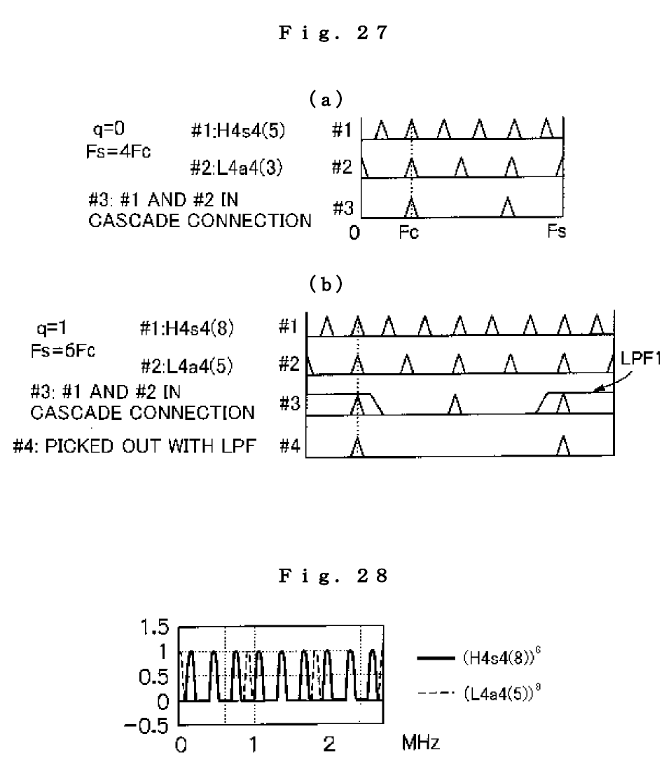

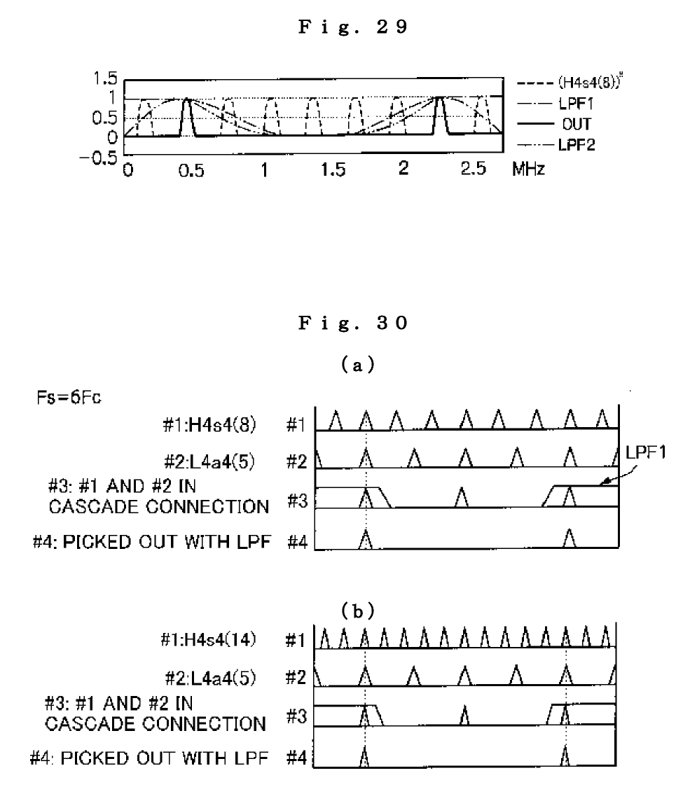

The bandwidth of a bandpass filter can be adjusted by the stage count (the number of M) of a basic highpass filter (H4s4 (k))^{M} or a basic lowpass filter (L4a4 (k)^{M} in cascade connection. In the example shown in FIG. 27(b), M=1 is taken for both of the basic highpass filter H4s4 (8) and the basic lowpass filter L4a4(5), but the frequency characteristic in case of taking M=8 for any of them will be shown in FIG. 28 and FIG. 29.

FIG. 28 is a diagram showing frequency characteristics of a basic highpass filter (H4s4 (8))⁸ and a basic lowpass filter (L4a4 (5))⁸ in an overlapped fashion, and the only mutually overlapped portions can be extracted by connecting these filters in cascade connection. In addition, FIG. 29 is a diagram showing extraction of pass ranges by LPF1 or LPF2 and three bandpass ranges taken out as in FIG. 28 are filtered with the LPF1 or the LPF2 so that only the pass ranges at both ends can be taken out.

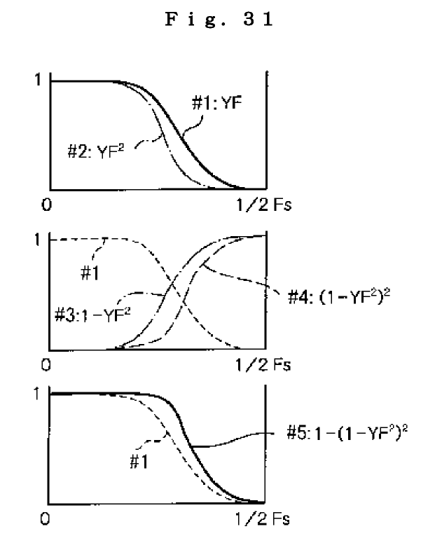

Next, means for adjusting bandwidths of the pass ranges narrowly by connection heterogeneous basic filters in cascade connection will be described. As described with reference to FIG. 25 and FIG. 26, an increase in the stage count of the homogeneous basic lowpass filters in cascade connection will do in order to narrow the bandwidth, but this has limitation. Here, a method that can make the bandwidth to get narrow further efficiently will be described. FIG. 30 is a diagram schematically showing the method.

FIG. 30(a) is the same as FIG. 27(b). In case of demanding a bandwidth narrower than this, as shown in FIG. 30(b), a basic highpass filter H4s4(14), for example, is used instead of the basic highpass filter H4s4 (8). The basic highpass filter H4s4(14) has a pass range with the center frequency Fc to become 450 kHz likewise the basic highpass filter H4s4(8) and moreover the bandwidth is 9/15=3/5 of the basic highpass filter H4s4(8).

Accordingly, using this basic highpass filter H4s4 (14), it is possible to narrow the bandwidth efficiently without increasing the stage count of filters in cascade connection. In addition, since the basic highpass filter H4s4(14) is only increased in the number of “0” to be inserted between respective filter coefficients, the tap count actually taken out as coefficients will not increase at all nor the circuit size will get large. Here, an example of using the basic highpass filter H4s4(14) has been described, but it is possible to likewise use any basic filter having the pass range at the same center frequency Fc=450 KHz.

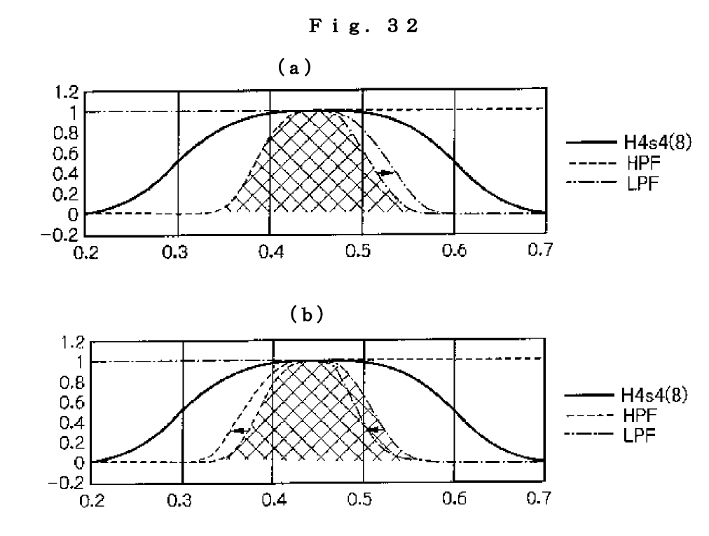

Next, means for adjusting the bandwidth of the pass range to get wider by connecting the homogeneous basic filters in cascade connection will be described. FIG. 31 is a diagram showing a frequency-gain characteristic for describing technique of adjusting bandwidth inclusive of inclination. Here, the frequency characteristic of the basic filter prior to adjustment will be indicated by YF. As described above, connecting two units of basic filters YF shown in #1 in cascade connection, inclination will get steep as shown in #2 so as to narrow the bandwidth (the clock position of −6 dB moves to the low frequency side).

And, with the central value (=0.5) of the gain as the axis, the frequency-gain characteristic of the basic filter YF2 shown with #2 is reversed (#3). This is derived by subtracting filter coefficients of the basic filter YF² from the unit pulse of the standard gain value “1” (equivalent to filter coefficients with the central value being 1 and all of the other being 0) together with delay (1−YF²). Here, this will be called a reversed basic filter.

Moreover, two units of the reversed basic filter shown with #3 will be connected in cascade connection. Inclination of frequency-gain characteristic derived thereby gets further steep as shown in #4 so as to narrow the bandwidth further as well (the clock position of −6 dB moves to the high frequency side). Here, the unit count of the reversed basic filter connected in cascade connection is set to two units, which is the same as in the case of #2, but may be taken more than this to make the moving amount toward the high frequency side larger than the moving amount toward the low frequency side mentioned earlier.

Lastly, with the central value (=0.5) of the gain as the axis, the frequency-gain characteristic shown with #4 is reversed (#5). This is derived by subtracting filter coefficients of #4 from the unit pulse of the standard gain value “1” together with delay (1−(1−YF²)²). In comparing the frequency characteristic of the original data #1 with the frequency characteristic of the post-adjustment data #5, the inclination in the frequency characteristic of the post-adjustment data #5 gets steeper than that in the original data #1 and the bandwidth gets wider.

The formula of the post-adjustment data #5 is expanded to derive the following:
1−(1−YF²)²
=1−1+2YF²−YF⁴
=2YF²−YF⁴ (Formula 1)
This Formula 1 is a formula derived in the case where two units each of the basic filter of #1 and the reversed basic filter of #3 are respectively connected in cascade connection, but the stage count in cascade connection will not limited hereto. However, in order to widen the bandwidth, it is preferable to make the stage count of #3 in cascade connection more than the stage count of #1 in cascade connection. In this case, the above described Formula 1 can be generalized as in the following Formula 2.
a*YF^{M1}−b*YF^{M2} (Formula 2)
Here, reference characters a and b denote coefficients (a>b), M1<M2 and reference character * denotes cascade connection.

Next, means for fine-tuning frequency of bandwidth will be described. FIG. 32 is a diagram showing a frequency-gain characteristic for describing technique of fine-tuning frequency. As shown in FIG. 32, a highpass filter (HPF) and a lowpass filter (LPF) are designed so that the pass ranges mutually overlap among comparatively wide pass ranges of the basic highpass filter H4s4(8). And, connecting these respective filters H4s4 (8), HPF and LPF in cascade connection, it is possible to derive a bandpass filter with the respective overlapping portions (diagonally shaded portions) to become pass ranges.

At that time, either the highpass filter HPF or a lowpass filter LPF or both of them undergo an operation of narrowing the pass range as shown in FIG. 25, FIG. 26 or FIG. 30 or an operation of widening the pass range as shown in FIG. 31 so that the bandwidth of the bandpass filter can arbitrarily undergo fine-tuning.

FIG. 32(a) shows an example of shifting only one side of a bandpass filter to the high frequency side by performing an operation of widening the pass range for the lowpass filter LPF. In addition, FIG. 32(b) shows an example of shifting both sides of a bandpass filter to the low frequency side without changing the bandwidth by performing an operation of widening the pass range for the highpass filter HPF and narrowing the pass range for the lowpass filter LPF.

<Rounding of Filter Coefficients>

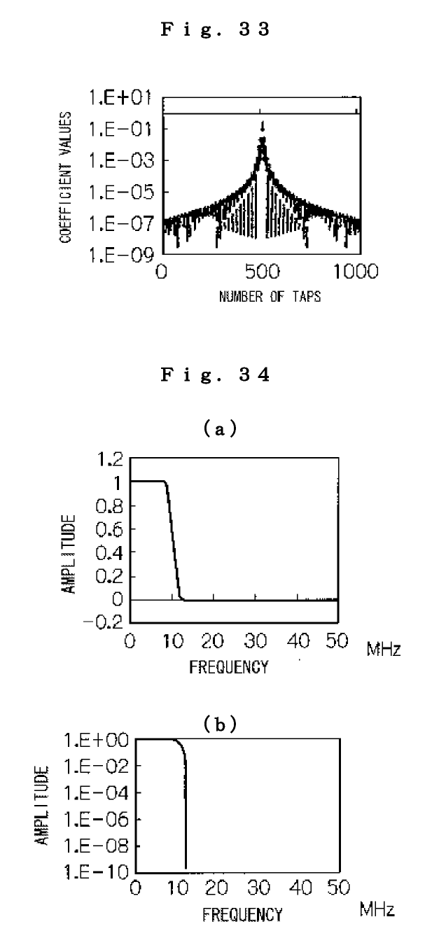

The sequence of numbers derived by cascade connection of basic filters, adjustment of bandwidth and the like as described above will become filter coefficients for realizing a desired frequency characteristic. Filter coefficient values (prior to rounding) actually calculated with a 16-bit operation accuracy have been graphed in FIG. 33. In addition, FIG. 34 is a diagram showing a frequency-gain characteristic of a digital filter prior to round the filter coefficients, where (a) indicates the gain by a linear scale and (b) indicates the gain by a logarithmic scale.

As shown in FIG. 33, the filter coefficient values derived by the designing method of the present embodiment will impart the maximum at the center (coefficient H₀). In addition, balance of the respective filter embodiment values will get significantly large compared with that of filter coefficients derived by a conventional filter designing method. That is, the respective filter coefficients derived by the designing method of the present embodiment are distributed and the value gets large locally in a region in the vicinity of the center and the values will get small in the other region so as to give rise to a distribution with high steepness making the balance between the filter coefficient values in the vicinity of the center and the periphery filter coefficient values will get significantly large. Therefore, even if filter coefficients with a value smaller than a predetermined threshold value are cut off by rounding, major filter coefficients of determining a frequency characteristic almost remain so as to hardly impart a bad effect to the frequency characteristic. In addition, although out-of-band attenuation of the frequency characteristic is subjected to the bit count of the filter coefficients, the frequency characteristic derived by the filter designing method of the present embodiment has, as shown in FIG. 34, extremely deep attenuation, and therefore even if the bit count may be decreased more or less, the desired attenuation can be secured.

Accordingly, it is possible to significantly reduce unnecessary filter coefficients by rounding. For example, the lower bits of filter coefficients are cut off and thereby the bit count is decreased so that all the filter coefficients with values smaller than the maximum value expressed only lower bits thereof are rounded to “0” and can be cut off. Accordingly, in order to decrease the number of filter coefficients, window multiplication as in a conventional case is not necessarily required. Here, as described above, basic filters in cascade connection will derive an impulse response forming a finite base function. Therefore, the number of filter coefficients designed based on this basic filter is less from the very first compared with conventional cases and can also be used directly without performing rounding. However, in order to decrease the tap counts further, rounding for decreasing the bit counts is preferably performed.

This point is a characteristic point of the present embodiment significantly different from the conventional filter designing method. That is, in the conventional filter designing method, the degree of steepness does not get so large in distribution of the demanded respective filter coefficients and therefore, performing rounding with the values of the filter coefficients, the major filter coefficients for determining a frequency characteristic are much likely to be cut off. In addition, it is also difficult to derive a frequency characteristic with extremely deep out-of-band attenuation, decrease in the bit counts of filter coefficients will make it impossible to secure a required out-of-band attenuation. Accordingly, in the conventional art, it was impossible to perform rounding for decreasing the bit counts, and therefore there used to be no choice but decreasing the number of the filter coefficients by window multiplication. Therefore, truncation errors occur in the frequency characteristic so that it was extremely difficult to derive a desired frequency characteristic.

In contrast, in the present embodiment, since it is possible to design a filter without performing the window multiplication, no truncation error will occur to the frequency characteristic. Accordingly, it will become possible to improve the cut off characteristic to an extremely large extent so as to make available a filter characteristic with a phase characteristic being linear and excellent.

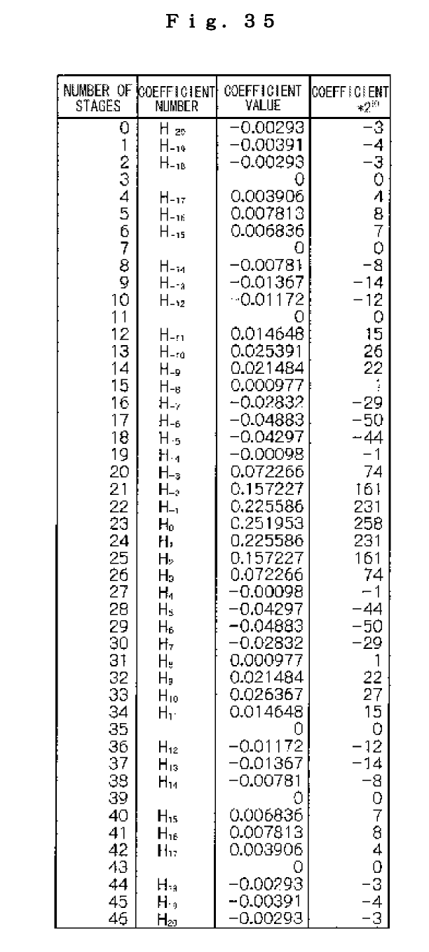

FIG. 35 is a diagram showing filter coefficients for 41 taps (46 stages being the stage count including the zero values) left as a result of undergoing 10-bits rounding to filter coefficients as in FIG. 33 calculated with, for example, 16-bits operation accuracy (processing of truncation off, truncation up or rounding onto the lower 10 bits or lower consisting of 16 bits to derive 10-bits data) and filter coefficient values derived by converting them to integer. The values of filter coefficients derived by connecting the basic filters in cascade connection as described above are decimal numbers and their number of digits can be decreased by 10-bits rounding. But they are a set of random values. This sequence of numbers may be directly used as filter coefficients. However, in order to make the number of multiplexer for use at the time of implementing a digital filter less, the numeric values of the filter coefficients may undergo rounding further so as to be simplified. Therefore, in the present embodiment, a sequence of numbers of filter coefficients rounded with 10 bits is multiplied by 2¹⁰ to convert the coefficient values into integers. Here, there described was an example of rounding the lower 10 bits and the still lower part of the filter coefficients consisting of 16 bits and thereafter multiplying the filter coefficients rounded to 10 bits with 2¹⁰ further to convert them into integers, but the filter coefficients consisting of 16 bits may be subjected to multiplying by 2¹⁰ directly and rounding (truncation off, truncation up or rounding off to the nearest integer and the like) of the fractional part of the resulting value derived so as to directly derive 10-bits filter coefficients converted to integers.

Performing such conversion-to-integer rounding operation, it will become possible to configure a digital filter to multiply, as shown in FIG. 50, filter coefficients in integer for output signals from respective taps of tapped delay line consisting of a plurality of delay devices (D-type flip-flop) 1 with a plurality of coefficient multipliers 2 individually, add the respective multiplied output all together with a plurality of adders 3 and thereafter multiply them by ½¹⁰ collectively with one shift computing unit 4. Moreover, integer filter coefficients can be expressed with addition in a binary system as in 2ⁱ+2^{j}+. . . (i and j are any integers). Thereby, instead of a multiplier, a bit shift circuit can be adopted to configure a coefficient multiplier so as to simplify configuration of the digital filter to be implemented.

FIG. 36 is a diagram showing a frequency-gain characteristic in the case of calculating filter coefficients with a 16-bit operation accuracy, thereafter rounding it to 10 bits (for example, the digits of 10 bits or lower are truncated) and moreover converting the outcome into an integer, where (a) indicates the gain by a linear scale and (b) indicates the gain by a logarithmic scale.

As clearly apparent from FIG. 36, the present embodiment does not undergo window multiplication at the time of filter designing and therefore rippling in the flat part in a frequency-gain characteristic is extremely small enough to fall within the range of ±0.3 dB. In addition, post-rounding out-of-band attenuation is approximately 44 dB and this out-of-band attenuation is subjected to the bit counts that hardware to be mounted is applicable. Accordingly, if hardware size is not limited, the post-rounding bits count is made large so as to make it possible to derive out-of-band attenuation characteristic with deeper attenuation.

Here, as an example of rounding, truncating off the lower bits for data of filter coefficients to perform rounding y-bits data to x bits was described, but rounding will not be limited hereto. For example, after the values of respective filter coefficients are compared with predetermined threshold values, the filter coefficients smaller than the threshold value may be arranged to be cut off. In this case, since the left filter coefficients are as the original y bits, these filter coefficients are multiplied by 2^{y} at the time of converting them to integers.

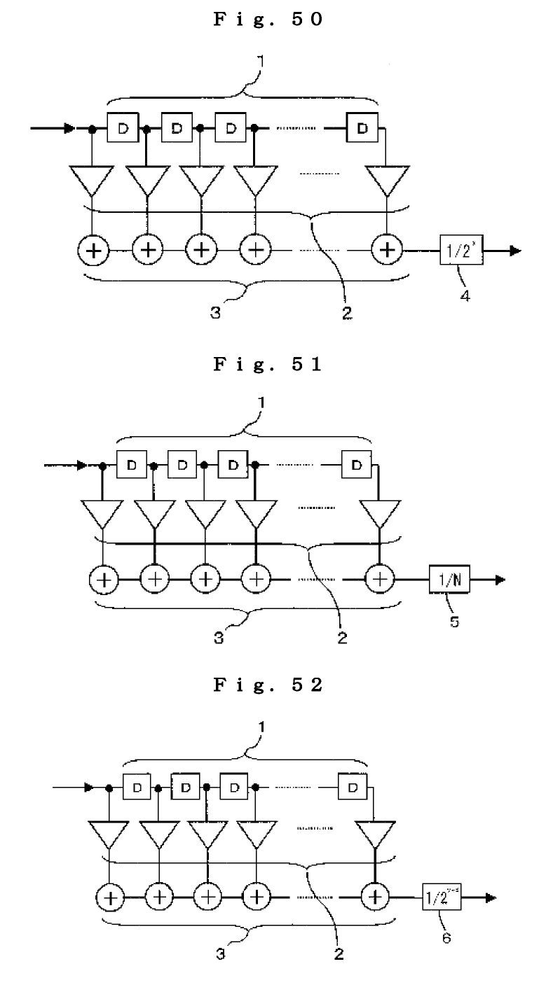

In addition, as another example of conversion-to-integer operation, the sequence of numbers of filter coefficients may be subjected to rounding of multiplying by N (N is a value beside power-of-two) on the fractional part (truncation off, truncation up or rounding off to the nearest integer and the like). In case of performing such conversion-to-integer N-fold rounding operation, it will become possible to configure a digital filter to multiply, as shown in FIG. 51, filter coefficients in integer for output signals from respective taps of tapped delay line consisting of a plurality of delay devices (D-type flip-flop) 1 with a plurality of coefficient multipliers 2 individually, add the respective multiplied output all together with a plurality of adders 3 and thereafter multiply them by 1/N collectively with one multiplier 5. Moreover, integer filter coefficients can be expressed with addition in a binary system as in 2ⁱ+2^{j}+. . . (i and j are any integers). Thereby, instead of a multiplier, a bit shift circuit can be adopted to configure a coefficient multiplier so as to simplify configuration of the digital filter to be implemented.

In addition, in case of multiplying the sequence of numbers by 2^{x} (x is an integer), it is possible to execute bits-unit rounding on filter coefficients while it is possible to execute inter-bits rounding on filter coefficients in case of multiplying a sequence of numbers by N. Bits-unit rounding refers to processing to multiply filter coefficients by an integer multiple of ½^{x} such as rounding all numeric values falling within the range of 2^{x} to 2^{x+1} to 2^{x} in case of multiplying a coefficient value by 2^{x} to cut off the fractional part for example. In addition, inter-bits rounding refers to processing to multiply filter coefficients by an integer multiple of 1/N such as rounding all numeric values falling within the range of N to N+1 to N in case of multiplying a coefficient value derived by N (for example, 2^{x-1}<N<2^{x}) to cut off the fractional part for example. By performing rounding multiplied by N, it is possible to adjust a value of filter coefficients to undergo conversion-to-integer into any value beside power-of-two. This will make it possible to delicately adjust the filter coefficient count (tap count) for use in a digital filter.

Otherwise, as an example of an rounding operation accompanying conversion-to-integer processing, all data values of y-bits filter coefficients smaller than ½^{x} may be regarded as zero while, as for the data values equal to or larger than ½^{x}, the data values are subjected to multiplying 2^{x-X}-fold (x+X<y) and rounding the decimal fractions (cut off, round up or rounding off to the nearest integer and the like). In case of performing such a rounding operation, it will become possible to configure a digital filter to multiply, as shown in FIG. 52, filter coefficients in integer for output signals from respective taps of tapped delay line consisting of a plurality of delay devices (D-type flip-flop) 1 with a plurality of coefficient multipliers 2 individually, add the respective multiplied output all together with a plurality of adders 3 and thereafter multiply them by ½^{x+X} collectively with one shift operation device 6. Moreover, integer filter coefficients can be expressed with addition in a binary system as in 2ⁱ+2^{j}+ . . . (i and j are any integers). Thereby, instead of a multiplier, a bit shift circuit can be adopted to configure a coefficient multiplier so as to simplify configuration of the digital filter to be implemented.

In addition, it is possible to significantly reduce the filter coefficient count (tap count) by regarding all data values smaller than ½^{x} as zero for cut-off and, at the same time, it is possible to derive filter coefficients having a good accuracy of (x+X) bits being abundant in bits count compared with x bits. Therefore a good frequency characteristic can be derived as well.

<Example of Mounting Filter Designing Apparatus>

An apparatus for realizing a method of designing a digital filter according to the above described present embodiment can be realized with any of hardware configuration, DSP and software. For example, the filter designing apparatus of the present embodiment, which is occasionally realized with software, is actually configured by a CPU or an MPU, a RAM, a ROM or the like of a computer and can be realized by a program stored in a RAM, a ROM, a hard disc or the like to operate.

For example, filter coefficients on the respective kinds of basic filters Lman, Lan, Hmsn, Hsn, Bmsn and Bsn are stored as data in advance in a storage device such as a RAM, ROM, a hard disc or the like. And a user designates any combination and connection order on the basic filters Lman, Lan, Hmsn, Hsn, Bmsn and Bsn, a zero value count k inserted between the respective filter coefficients, the homogeneous cascade connection count M for the basic filters and the like. Then the CPU can be arranged to derive filter coefficients corresponding to the designated contents by the operation described above with data of filter coefficients stored in the above described storage device. In that case, the storage device corresponds to the basic filter coefficient storing means of the present invention and the CPU corresponds to operating means of the present invention.

A user interface for a user to designate the combination and the connection order on the basic filters Lman, Lan, Hmsn, Hsn, Bmsn and Bsn, a zero value insertion count k and a cascade connection count M and the like can be configured arbitrarily. For example, types of basic filters (any of Lman, Lan, Hmsn, Hsn, Bmsn and Bsn) are made selectable by operation of a keyboard and a mouse from a listing table displayed on a screen and the values of the parameters m, n, k and M are made feasible to be inputted by operation of a keyboard and a mouse. And, the input order at the time of implementing selection of types and inputting of parameters sequentially one by one is inputted as a connection order of basic filters. The CPU obtains thus inputted information to derive filter coefficients corresponding to the contents designated by that input information with an operation described above.

In addition, respective types of basic filters Lman, Lan, Hmsn, Hsn, Bmsn and Bsn are iconized so as to be arranged to be displayed on a display screen (filter coefficients corresponding to the respective icons are stored as data in a storage device), and a user arbitrarily combines and disposes these icons on a display screen by operation of a keyboard and a mouse. In addition, the other necessary parameters are inputted by operation of a keyboard and a mouse. And, the CPU may be arranged to automatically operate and derive arrangement of icons and filter coefficients corresponding to input parameters.

In addition, utilizing mathematical function of spreadsheet software installed in a personal computers and the like, it is also possible to perform a moving average operation at the time of deriving basic filters and an operation of convolution at the time of connecting basic filters in cascade connection, and the like. Operations in this case are actually performed by a CPU, a ROM, a RAM and the like of a personal computer and the like in which spreadsheet software is installed.

In addition, the derived filter coefficients undergo FFT transformation automatically, a result thereof may be arranged to be displayed as frequency-gain characteristic diagram on a display screen. This will enable visual confirmation on the designed filter frequency characteristic and enable filter designing more easily.

<Example of Mounting Digital Filter>

In case of actually implementing a digital filter inside an electronical device and semiconductor IC, it is advisable to configure an FIR filter having a sequence of numbers finally derived as filter coefficients by a filter designing apparatus as described above. That is, as shown in FIG. 50 to FIG. 52, one digital filter is configured only by a plurality of D-type flip-flops 1, a plurality of coefficient multipliers 2, a plurality of adders 3, one bit shift circuit 4, 6 or multiplier 5, and the final filter coefficients derived through procedure as described above are configured in a form to be set in a plurality of coefficient multipliers 2 inside the digital filter.

In that case, the number of the derived filter coefficients are significantly reduced by 10-bits rounding and converted to simple integers by 2¹⁰-th conversion-to-integer processing. Accordingly, the tap count is extremely small and basically the part of the coefficient multiplier 2 does not require any multiplier but a bit shift circuit is applicable so that a desired frequency characteristic can be realized with a high accuracy in a small circuit size.

Here, basic filters used for filter designing may be configured as hardware respectively so that they are connected as hardware to mount a digital filter.

As described above in detail, according to the first embodiment, the filter coefficients are calculated in such a form that more than one basic filters are combined and connected arbitrarily in cascade connection and moreover unnecessary filter coefficients are arranged to be significantly reduced by rounding, and thereby, the tap count can be significantly reduced compared in case of conventional FIR filters. In addition, by converting the filter coefficients into integers, coefficient multipliers at the respective tap output ports can be configured by a bit shift circuit, no multiplier will become necessary so that almost all configuration consists of D-type flip-flops and adder-subtractors. Accordingly, the number of circuit elements is significantly reduced so that circuit size can be made small and reduction in power consumption, alleviation in operation load and the like can be realized.

Moreover, since it is possible to significantly reduce the number of unnecessary filter coefficients by rounding, it is possible to make the conventional window multiplication unnecessary in order to reduce the number of filter coefficients. Since it is possible to design a digital filter without performing the window multiplication, no truncation error will occur to the frequency characteristic. Accordingly, it is possible to realize a desired frequency characteristic of a digital filter with a high accuracy.

In addition, it is possible to configure a digital filter only by combination of basic filters so that designing will become a work of synthesizing frequency characteristics on the actual frequency axis. Accordingly, filter designing is simple and easy to think and even those unskilled in the art can implement filter designing extremely simply and sensuously.

### Second Embodiment

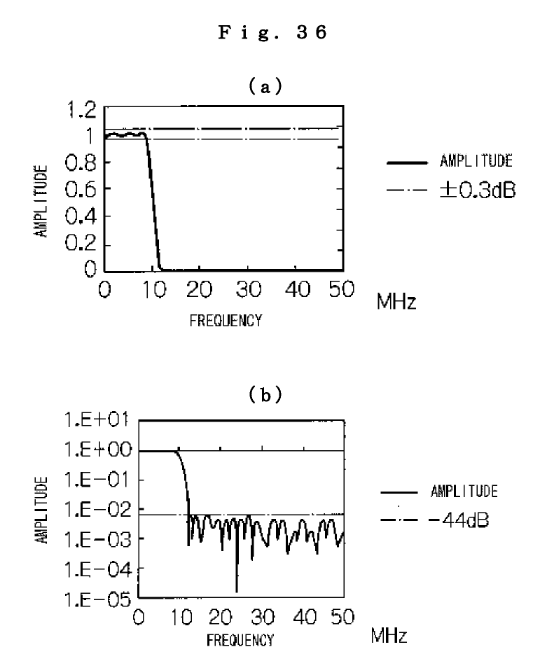

Next, a second embodiment of the present invention will be described based on the drawings. FIG. 37 is a flow chart showing procedure of a method of designing a digital filter according to the second embodiment. In addition, FIG. 38 is a diagram showing a frequency characteristic for describing a concept of a method of designing a digital filter according to the second embodiment.

In FIG. 37, first filter coefficients with a sequence of numbers being symmetric are generated at first (Step S1). A method of generating this first filter coefficient will not be limited in particular. If the sequence of numbers of filter coefficients is symmetric, a conventional designing method in use of the approximation formula and the window function may be used. In addition, after inputting a plurality of amplitude values expressing a desired frequency characteristic and bringing the inputted sequence of numbers into inverse Fourier transform, the derived sequence of numbers may undergo window multiplication to derive the first filter coefficients. In addition, the designing method described in the first embodiment may be employed. Preferably with the designing method described in the first embodiment (except rounding), the first filter coefficients are generated.

A frequency characteristic indicated by the reference character A in FIG. 38 exemplifies a frequency-gain characteristic of an original filter realized by the first filter coefficients generated in Step S1.

Next, there is derived symmetric second filter coefficients of realizing a frequency-gain characteristic (the reference character B in FIG. 38) having a contact at a position imparting a local maximum value in a frequency-gain characteristic (the reference character A in FIG. 38) expressed by the first filter coefficients and imparting a local minimum value at the relevant contact (Step S2). If the frequency-gain characteristic has such a characteristic, the second filter coefficients may be generated with any method and can be derived, for example, by an operation as follows.

That is, in case of taking {H₋ᵢ, H₋₍ᵢ₋₁₎, . . . , H₋₁, H₀, H₁, . . . , Hᵢ₋₁, Hᵢ} (H₀ is the central value and is of a symmetric type with the central value being the border. H₋ᵢ=Hᵢ, H₋₍ᵢ₋₁₎=Hᵢ₋₁, . . . , H₋₁=H₁) as a sequence of numbers of the first filter coefficients configuring the original filter, the second filter coefficients are derived by an operation of {−αH₋ᵢ, −αH₋₍ᵢ₋₁₎, . . . −αH₋₁, −αH₀+(1+α), −αH₁, . . . , −αHᵢ₋₁, −αHᵢ}} (α is any positive number). That is, all the coefficients beside the central value are multiplied by −α while only the central value is multiplied by −α and moreover (1+α) is added thereto, and thereby the second filter coefficients are derived. The filter having second filter coefficients will be called “adjustment filter” below.

After thus deriving the second filter coefficients, there is performed an operation of deriving third filter coefficients derived in the case where the original filter having the first filter coefficients and the adjustment filter having the second filter coefficients are connected in cascade connection (Step S3). By connecting the original filter and the adjustment filter in cascade connection, the first filter coefficients and the second filter coefficients undergo multiplication and addition to create new filter coefficients. Contents of an operation of cascade connection are as described in the first embodiment.

And, for the third filter coefficients generated thereby, unnecessary filter coefficients are significantly reduced by rounding to reduce the bit count and the filter coefficients are simplified by conversion-to-integer processing (Step S4).

Here, likewise the first embodiment as well, processing of reducing the bit count of filter coefficients and processing of converting filter coefficients into integers are not necessarily implemented separately, but by multiplying filter coefficients with 2^{x} or N directly and rounding the number after the decimal point of the value derived as a result thereof (cut off, round up or rounding off to the nearest integer and the like), the processing of decreasing the bit count of filter coefficients and the processing of converting filter coefficients into integers may be concurrently implemented by one rounding operation. In addition, making those with y-bits filter coefficients smaller than ½^{x} into zero and those with filter coefficients equal to ½^{x} or larger, (x+X)-bits filter coefficients converted to integers subject to multiplying filter coefficients by 2^{x+X}(x+X<y) and rounding the number after the decimal point of the value may be arranged to be derive.

Also in the second embodiment, in order to decrease the number of filter coefficients, window multiplication as in a conventional case is not necessarily required. Since it is possible to design a digital filter without performing the window multiplication, no truncation error will occur to the frequency characteristic. Accordingly, it will become possible to improve the cutoff characteristic to an extremely large extent so as to make available a filter characteristic with a phase characteristic being linear and excellent.

Here, such an example that one adjustment filter is connected to the original filter in cascade connection has been exemplified for description, but a plurality of adjustment filters may be arranged to be brought in to cascade connection. In that case, as indicated by a dotted arrow in FIG. 37, regarding third filter coefficients generated in Step S3 as first filter coefficients, the step returns to Step S2. And, based on the new first filter coefficients (corresponding to a sequence of numbers outputted from the adjustment filters at the first stage in case of inputting a single pulse to the original filters), second filter coefficients are derived again (new adjustment filters are generated).

Moreover, performing an operation of convolution on the thus generated new first filter coefficients and new second filter coefficients, new third filter coefficients derived in case of further connecting new adjustment filters in cascade connection are operated. After repeating such an operation for the number of adjustment filters desired for cascade connection, rounding processing of Step S4 is executed onto third filter coefficients generated in Step S3 of the final stage.

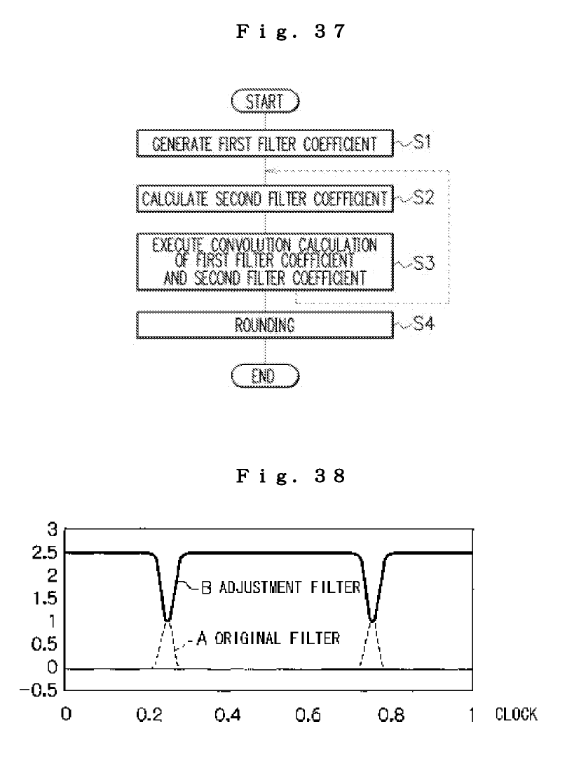

FIG. 39 is a diagram showing a frequency-gain characteristic of an original filter (bandpass filter) and a diagram showing a frequency-gain characteristic derived in case of connecting one to three adjustment filters in cascade connection to this original bandpass filter. In FIG. 39, reference numeral 41 denotes a frequency-gain characteristic of an original filter; reference numeral 42 denotes a frequency-gain characteristic derived in case of connecting one adjustment filter in cascade connection; reference numeral 43 denotes a frequency-gain characteristic derived in case of connecting two adjustment filters in cascade connection; and reference numeral 44 denotes a frequency-gain characteristic derived in case of connecting three adjustment filters in cascade connection respectively.

As shown in this FIG. 39, by connecting the adjustment filters of the present embodiment in cascade connection to the original filter, it is possible to widen pass bandwidth of the filter and steepen an inclination of a blocking range. Making the number of adjustment filters brought in cascade connection abundant, it is possible to derive a steeper filter characteristic with wider pass bandwidth.

Here, this FIG. 39 shows a frequency characteristic in case of making the value of the parameter α to 1.5 at the time of the second filter coefficients from the first filter coefficients. As shown in FIG. 39, in case of α≠1, slight overshoot and ringing take place at the top part of the frequency characteristic. However, in case of α=1, overshoot and ringing will never take place at the top part of the frequency characteristic but give rise to a flat characteristic.

FIG. 40 is a diagram for describing a principle of change in a frequency characteristic derived in case of connecting, in cascade connection, an adjustment filter according to the present embodiment. Here, this FIG. 40 is for describing the basic principle and does not match the waveform of the frequency characteristic shown in FIG. 39. This FIG. 40 shows the principle in case of α=1.

FIG. 40(a) shows change in a frequency-gain characteristic in the case where the first unit of adjustment filters has been connected to the original filter in cascade connection. In FIG. 40 (a), reference character A denotes a frequency-gain characteristic of the original filter; reference character B denotes a frequency-gain characteristic of the first unit of adjustment filter having the second filter coefficients generated from the first filter coefficients that the original filter has; and reference character C denotes a frequency-gain characteristic derived in case of connecting the first unit of adjustment filter to the original filter in cascade connection.

That is, a new frequency-gain characteristic C in case of connecting one unit of adjustment filter to the original filter in cascade connection will be such a form subject to multiplication of the frequency-gain characteristic A of the original filter with the frequency-gain characteristic B of the adjustment filter. In case of further connecting the second unit of adjustment filter in cascade connection, third filter coefficients corresponding to a such generated frequency-gain characteristic C are used as first filter coefficients newly to derive new second filter coefficients on the second unit of adjustment filter.

FIG. 40(b) shows change in a frequency-gain characteristic in the case where the second unit of adjustment filters has been connected further in cascade connection. In FIG. 40 (b), reference character A′ denotes a frequency-gain characteristic in case of connecting the first unit of adjustment filter in cascade connection and is the same as the frequency-gain characteristic C derived by the procedure in FIG. 40 (a). Reference character B′ denotes a frequency-gain characteristic of the second unit of adjustment filter having the new second filter coefficients generated from the new first filter coefficients corresponding to the frequency-gain characteristic A′. Reference character C′ denotes a new frequency-gain characteristic derived in case of further connection the second unit of adjustment filters in cascade connection and is configured by multiplying the two frequency-gain characteristic A′ and B′ together.

This is not depicted but in case of further connecting the third unit of adjustment filter in cascade connection, filter coefficients corresponding to the new frequency-gain characteristic C′ generated with the procedure in FIG. 40 (b) are used as first filter coefficients again to derive new second filter coefficients on the third unit of adjustment filters. And following the procedure similar to that described above, the new frequency-gain characteristic is derived.

Thus, by connecting a plurality of adjustment filters in cascade connection to the original filter, it is possible to widen pass bandwidth of the filter and steepen an inclination of a blocking range. In case of α=1, the frequency-gain characteristic of the original filter is axisymmetric to the frequency-gain characteristic of the adjustment filter with a line of “1” for amplitude as the border. Accordingly, even if any units of adjustment filters are connected in cascade connection, the mutually multiplied frequency-gain characteristic of the new filter will not exceed the line of amplitude “1” so that neither overshoot nor ringing will occur. Thereby, the value of α is preferably set to “1”.

On the other hand, making the value of α larger than 1, overshoot or ringing occurs more or less, but it is possible to enlarge the rate of pass bandwidth that can be widened per connection of one unit of adjustment filter. Accordingly, in the case where the pass bandwidth is desired to be widened efficiently with less units of adjustment filters, it is advisable to enlarge the value of α. In this case, after a plurality of stages of the adjustment filters having derived the second filter coefficients with α≠1 are connected in cascade connection, the adjustment filter with α=1 is connected to the last stage. Thereby it is possible to widen the pass bandwidth efficiently and derive a good frequency characteristic without any overshoot and ringing.

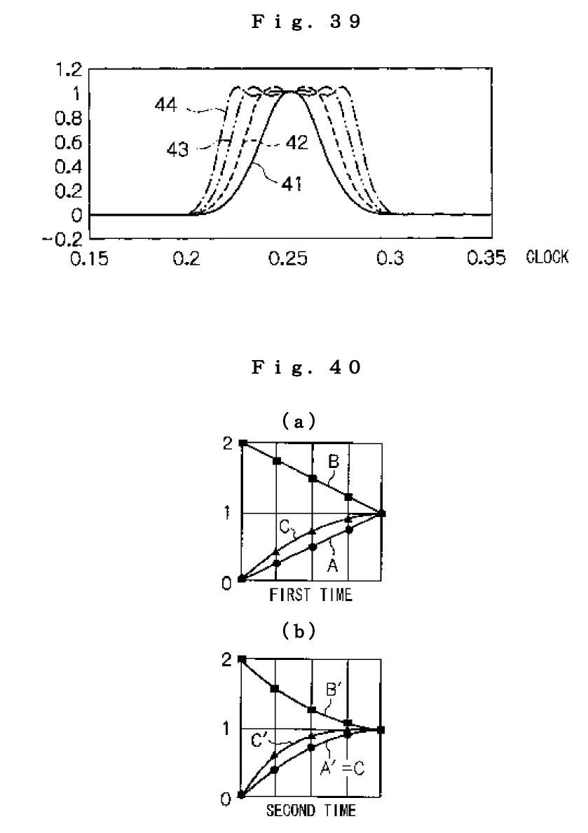

FIG. 41 is a diagram showing a frequency characteristic derived in case of connecting, to an original filter, three stages of adjustment filters with α=1.5 in cascade connection and further connecting an adjustment filter with α=1 in cascade connection to the last stage. As apparent from this FIG. 41, connecting the adjustment filter with α=1 to the last stage, it is possible to derive a good frequency characteristic with pass bandwidth being wide, the inclination in the blocking range being steep and the top part being flat. In addition, since the filter coefficients are symmetric, linearity in phase can be secured. In addition, adjusting the value of α as α<1, it is possible to delicate adjustment on frequency pass bandwidth.

So far, an example of designing a bandpass filter has been described, it is possible to design a lowpass filter, a highpass filter and the like with the likewise procedure. FIG. 42 is a diagram showing a frequency-gain characteristic of an original lowpass filter and a diagram showing a frequency-gain characteristic derived in case of connecting one to five adjustment filters in cascade connection to this original lowpass filter. This FIG. 42 shows a frequency characteristic of α=1.

In FIG. 42, reference numeral 51 denotes a frequency-gain characteristic of an original lowpass filter, and reference numerals 52 to 56 denote a frequency-gain characteristic derived in case of connecting one to five units of adjustment filters in cascade connection respectively. As shown in this FIG. 42, likewise the bandpass filter of FIG. 39, also in case of lowpass filter, it is possible to widen the pass bandwidth of the filter and steepen the inclination of the blocking range by connecting the adjustment filters in cascade connection. In addition, increasing the number of adjustment filters to be connected in cascade connection, it is possible to derive a filter characteristic with the bassbandwidth being wider and the inclination being steeper.

It is possible to realize an apparatus for realizing a filter designing method according to the second embodiment described so far with any of hardware configuration, DSP and software. For example, in case of realizing a filter designing apparatus in the present embodiment with software, it is actually configured by CPU or MPU, RAM, ROM or the like of a computer and can be realized by operating a program stored in the RAM, the ROM or the hard disc and the like.

It is possible to derive the first filter coefficients by employing a configuration likewise the fist embodiment. That is, filter coefficients on respective types of basic filters Lman, Lan, Hmsn, Hsn, Bmsn and Bsn are stored in a storage apparatus as data. And when a user instructs any combination on the basic filters Lman, Lan, Hmsn, Hsn, Bmsn and Bsn, a connection order, a zero value count k inserted between respective filter coefficients, cascade-connected homogeneous basic filter count M and the like, the CPU derives filter coefficients corresponding to the instructed contents with the above described operation with data of the filter coefficients stored in the above described storage apparatus.

In addition, it is possible to derive the second filter coefficients of an adjustment filter from the first filter coefficients by the CPU multiplying all the filter coefficients beside the center value of a sequence of numbers by −α while multiplying only the center value by −α and moreover adding (1+α). In addition, it is possible to derive the third filter coefficients by connection in cascade connection from the first filter coefficients and the second filter coefficients by the CPU performing an operation as in the above described FIG. 24. Moreover, it is possible to perform rounding of filter coefficients automatically with the CPU.

In addition, utilizing mathematical function of spreadsheet software installed in a personal computers and the like, it is also possible to perform an operation of deriving the first filter coefficients, an operation of deriving the second filter coefficients, an operation of deriving the third filter coefficients and an operation of rounding the third filter coefficients. Operations in this case are actually performed by the CPU, the ROM, the RAM and the like of a personal computer and the like in which spreadsheet software is installed.

In addition, the derived filter coefficients undergo FFT transformation automatically, a result thereof may be arranged to be displayed as frequency-gain characteristic diagram on a display screen. This will enable visual confirmation on the designed filter frequency characteristic and enable filter designing more easily.

In case of actually implementing a digital filter inside an electronical device and semiconductor IC, as shown in FIG. 50 to FIG. 52, configuration of an FIR filter is done if it has a sequence of numbers finally derived as filter coefficients by a filter designing apparatus as described above. Also in this case, the derived filter coefficients have been significantly reduced in count by rounding and are converted into simple integers. Accordingly, no multiplier is required basically but a bit shift circuit is applicable so that a desired frequency characteristic can be realized with a high accuracy in a small circuit size.

Here, an original filter and an adjustment filter may be configured as hardware respectively so that they are connected as hardware to mount a digital filter.

### Third Embodiment

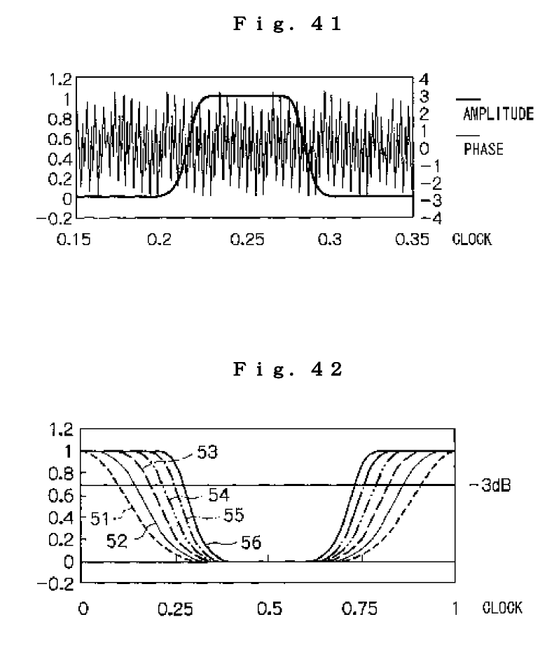

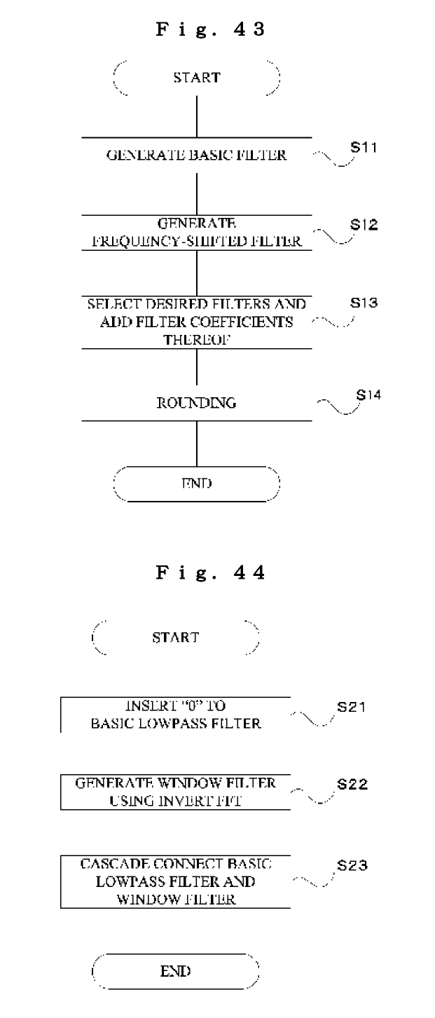

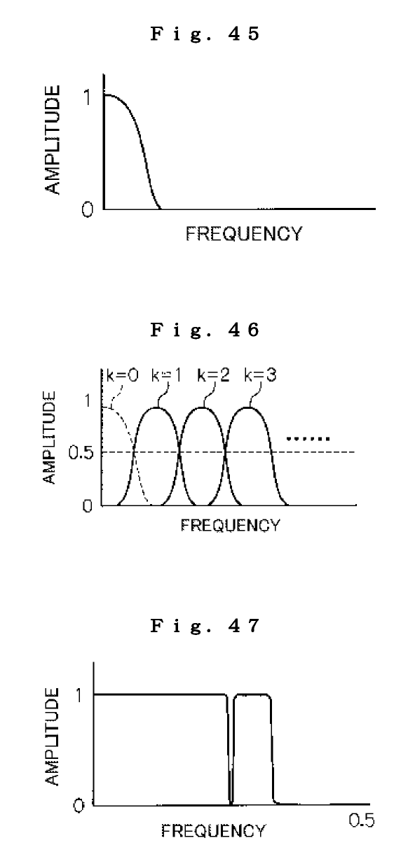

Next, a third embodiment of the present invention will be described based on the drawings. FIG. 43 and FIG. 44 are flow charts showing procedure of a method of designing a digital filter according to the third embodiment. In addition, FIG. 45 to FIG. 48 are diagrams showing a frequency characteristic for describing a concept of a method of designing a digital filter according to the third embodiment.

FIG. 43 is a flow chart showing a holistic processing flow of a digital filter designing method according to the third embodiment. In FIG. 43, a basic filter with a sequence of numbers of filter coefficients being symmetric is generated at first (Step S1). This basic filter has a frequency-gain characteristic having pass bandwidth of 1/β (β being an integer not less than 1) of a sampling frequency fₛ of a signal to become a processing subject for filtering. FIG. 45 shows a frequency-gain characteristic of a basic filter. This FIG. 45 shows a frequency-gain characteristic of a basic filter having bandwidth derived by dividing a half of the sampling frequency fₛ by 128.

Next, by performing a frequency shift operation on the basic filter having a frequency-gain characteristic as in FIG. 45, there are generated a plurality of frequency shift filters with the frequency-gain characteristic of the basic filter subject to shift in every predetermined frequency so that the mutually adjacent filter groups overlap in the part of amplitude ½ (Step S12). Such a frequency shift can be derived by an operation as follows.

In case of {H₋ᵢ⁰, H₋₍ᵢ₋₁₎⁰, H₋₍ᵢ₋₂₎⁰, . . . , H₋₁⁰, H₀⁰, H₁⁰, . . . , Hᵢ₋₂⁰, Hᵢ₋₁⁰, Hᵢ⁰} (being symmetric with coefficient H_{C}⁰ as the center) being a sequence of filter coefficients of the basic filter and {H₋ᵢ^{γ}, H₋₍ᵢ₋₁₎^{γ}, H₋₍ᵢ₋₂₎^{γ}, . . . , H₋₁^{γ}, H₀^{γ}, H₁^{γ}, . . . , Hᵢ₋₂^{γ}, Hᵢ₋₁^{γ}, Hᵢ^{γ}} being a sequence of filter coefficients of the γ-th unit of frequency shift filter counted from the basic filter (with a frequency-gain characteristic of the basic filter subject to frequency shift only by “predetermined frequency x γ”), a coefficient Hⱼ^{γ} of the coefficient number j (j=−i, −(i−1), −(i−2), . . . , −1, 0, 1, . . . , i−2, i−1, i) in the γ-th unit of frequency shift filter is derived by
Hⱼ^{γ}=Hⱼ⁰*2 cos (2πγj/(β/2)).

For example, a coefficient H₋ᵢ^{γ} with the coefficient number being −i in the γ-th unit of frequency shift filter is derived by
H₋ᵢ^{γ}=H₋ᵢ⁰*2 cos (2πγ*(−i)/(β/2)).
In addition, a coefficient H₋₍ᵢ₋₁₎^{γ} with the coefficient number being −(i−1) is derived by
H₋₍ᵢ₋₁₎^{γ}=H₋₍ᵢ₋₁₎^{C}*2 cos (2πγ*(−(i−1)/(β/2)).
The other coefficients {H₋₍ᵢ₋₂₎^{γ}, . . . , H₋ᵢ^{γ}, H₀^{γ}, H₁^{γ}, . . . , Hᵢ₋₂^{γ}, Hᵢ₋₁^{γ}, Hᵢ^{γ}} are derived by a likewise operation.

FIG. 46 shows a frequency-gain characteristic that a plurality of frequency shift filters generated in this Step S12 have (a frequency-gain characteristic of a basic filter is depicted in a dotted line). Subject to processing in the above described Step S11 and Step S12, a filter coefficient group of a plurality of filters with the frequency-gain characteristic with the filter groups overlapping mutually in the part of amplitude ½ is derived. The unit count of filters generated by frequency shift is optional but in the case where bandwidth of the basic filter is derived by splitting a half of the sampling frequency fₛ into 128 fragments, the total comes to 128 units in total inclusive of the basic filter and the frequency shift filter. The frequency rage determined by the unit counts of filter generated will become a designing area of a digital filter as the last product.

And, taking out one or more filters arbitrarily from a plurality of filters generated in the above described Step S11 and Step S12, filter coefficients thereof having corresponding coefficient numbers are added to thereby derive new filter coefficients (Step S13). For example, in case of adding the γ-th unit of frequency shift filter counted from the basic filter to the (γ+1)-th unit of frequency shift filter, filter coefficients to be derived will be
{H₋ᵢ⁶⁵+H₋ᵢ^{γ+1}, H₋₍ᵢ₋₁₎⁶⁵+H₋₍ᵢ₋₁₎^{γ+1}, H₋₍ᵢ₋₂₎^{γ}+H₋₍ᵢ₋₂₎^{γ}, . . . , H₋₁^{γ}+H₋₁^{γ-1}, H₀^{γ}+H₀^{γ+1}, H₁^{γ}+H₁^{γ+1}, . . . , Hᵢ₋₂^{γ}Hᵢ₋₂^{γ+1}, Hᵢ₋₁^{γ}+Hᵢ₋₁^{γ+1}, Hᵢ^{γ}+Hᵢ^{γ+1}}.

FIG. 47 is a diagram showing an example of a frequency-gain characteristic that a digital filter generated in this Step S13 has. Here, in this FIG. 47, the scale of the frequency axis is significantly compressed compared with FIG. 45 and FIG. 46. The frequency-gain characteristic shown in this FIG. 47 shows a frequency characteristic of a digital filter generated by taking out a plurality of filters corresponding to γ=0 to 31 and γ=33 to 38 and adding those filter coefficients having corresponding coefficient numbers together.

As described above, since the mutually adjacent filters are made so as to mutually overlap just in the part of the amplitude ½, addition of those filter coefficients will make the amplitude to just “1”. Consequently, the top part of the pass range of the derived filter is flattened. Accordingly, adding 32 units of filter coefficients corresponding to γ=0 to 31, the top parts of those 32 units of filters are flattened to derive a pass range having bandwidth of (fₛ/2/128)×32. In addition, the filter corresponding to γ=32 is not a subject of addition, a trap will occur in that part. Moreover, adding six units of filter coefficients corresponding to γ=33 to 38, the top parts of those six filters are flattened to derive a pass range having bandwidth of (fₛ/2/128)×6. As described so far, it is possible to derive a specially shaped lowpass filter having a passband range in the part of γ=0 to 38 and a trap in the part of γ=32.

Next, for the filter coefficients generated in Step S13, unnecessary filter coefficients are significantly reduced by rounding to reduce the bit count and the filter coefficients are simplified by conversion-to-integer processing (Step S14).

Here, likewise the first embodiment as well, processing of reducing the bit count of filter coefficients and processing of converting filter coefficients into integers are not necessarily implemented separately, but by multiplying filter coefficients with 2^{x} or N directly and rounding the number after the decimal point of the value derived as a result thereof (truncation off, truncation up or rounding off to the nearest integer and the like) the processing of decreasing the bit count of filter coefficients and the processing of converting filter coefficients into integers may be concurrently implemented by one rounding operation. In addition, making those with y-bits filter coefficients smaller than ½^{x} into zero and those with filter coefficients equal to ½^{x} or larger, (x+X)-bits filter coefficients converted to integers subject to multiplying filter coefficients by 2^{x+X} (x+X<y) and rounding the number after the decimal point of the value may be arranged to be derive.

Also in the third embodiment, in order to decrease the number of filter coefficients, window multiplication as in a conventional case is not necessarily required. Since it is possible to design a digital filter without performing the window multiplication, no truncation error will occur to the frequency characteristic. Accordingly, it will become possible to improve the cutoff characteristic to an extremely large extent so as to make available a filter characteristic with a phase characteristic being linear and excellent.

Next, a method of generating a basic filter in the above described Step S11 will be described in detail. In the present invention, a method of generating this basic filter will not be limited in particular. If the sequence of numbers of filter coefficients is symmetric, it is possible to apply various generation methods. For example, a conventional designing method in use of the approximation formula and the window function may be used. In addition, a designing method of bringing a plurality of amplitude values expressing a desired frequency characteristic into inverse Fourier transform. In addition, the designing method (except rounding) described in the first embodiment may be employed.

FIG. 44 is a flow chart showing an example of processing of generating a basic filter. In FIG. 44, at first, a plurality of “0”s are inserted between a sequence of numbers of a basic filter such as the first embodiment having symmetric basic sequence of numbers as filter coefficients to adjust filter band (Step S21). For example, “0” is inserted individually among a sequence of numbers as in {−1, 0, 9, 16, 9, 0, −1} configuring filter coefficients of a basic lowpass filter L4a4.

As shown in FIG. 23, the basic lowpass filter L4a4 with filter coefficients consisting of the sequence of numbers of {−1, 0, 9, 16, 9, 0, −1} realizes a lowpass filter characteristic having a pass range individually at both sides of the center frequency. Inserting “0” individually among filter coefficients of such a basic lowpass filter L4a4, the frequency axis of a frequency-gain characteristic thereof (cycle in the frequency direction) will become ½ so as to increase the pass range count twice larger. Likewise, taking k units of “0” inserted between the filter coefficients, the frequency axis of a frequency-gain characteristic thereof will become 1/(k+1).

Accordingly, taking 127 units as the number of “0” to be inserted, there derived is a frequency-gain characteristic of a lowpass filter having bandwidth as a pass range derived by dividing a half of the sampling frequency fₛ by 128. However, since this will still present a frequency characteristic of a continuous wave with 128 units of pass ranges being present inside a band lower than the central frequency, it is necessary to cut out a frequency characteristic of a single wave configuring basic filter as in FIG. 45 from this continuous wave. Processing in Step S22 and Step S23 described below implements this cutout operation.

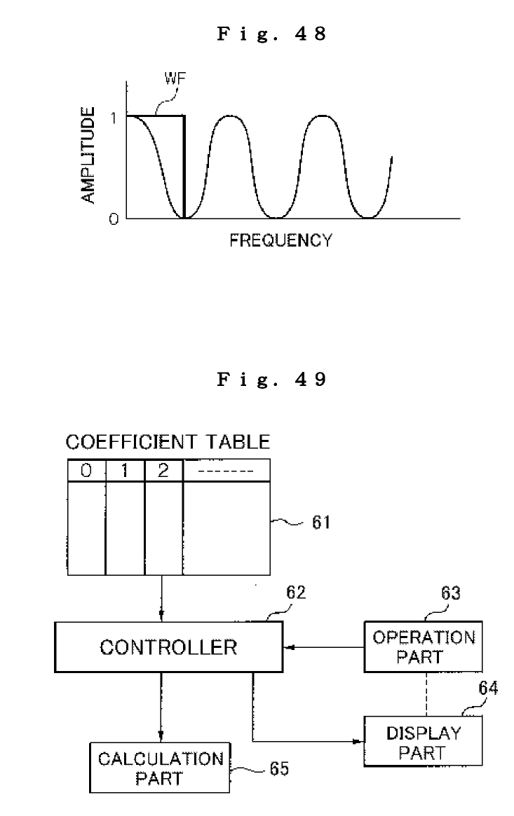

At the time of implementing a cutout operation of a single wave, a window filter WF as shown in FIG. 48 is generated at first (Step S22). This window filter WF has a same pass range as a pass range of an only single wave to be extracted as a basic filter as in FIG. 45. And connecting such a window filter WF and a basic lowpass filter L4a4 (127) in cascade connection, the basic filter as in FIG. 45 is extracted (Step S23). It is possible to connect this window filter WF and the basic lowpass filter L4a4 (127) in cascade connection by operating filter coefficients as described in FIG. 24.

In the present invention, a method of generating the window filter WF will not be limited in particular, but it is possible to apply various generation methods. As an example, there is a method of inputting a plurality of amplitude values expressing a frequency characteristic of a window filter WF to bring the relevant inputted sequence of numbers into inverse Fourier transform. As known well, implementing Fourier transform (FFT) on a certain sequence of numbers, waveform of a frequency-gain characteristic corresponding to the sequence of numbers thereof is derived. Accordingly, inputting a sequence of numbers expressing waveform of a desired frequency-gain characteristic and bring them into inverse Fourier transform to extract the real term, the original sequence of numbers necessary for realizing the relevant frequency-gain characteristic is derived. That sequence of numbers corresponds to the filter coefficients of the window filter WF to be derived.

Here, in order to configure an ideal filter, infinite units of filter coefficients are required and it is necessary to make the filter tap count into unlimited number of units. Accordingly, in order to make the error from the desired frequency characteristic small, the number of input data corresponding to the filter coefficient count is preferably made abundant until the frequency error falls within a required range. However, as for the window filter WF, it will do if all pass range only enough for the basic filter is included in the pass range, no accuracy more than that is required. Therefore, the input data count (the filter coefficient count of the window filter WF) of the sequence of numbers may not be made so abundant.

As for input of amplitude value expressing a frequency characteristic of a window filter WF, numeric values of individual sample points may be inputted directly or desired frequency characteristic waveform may be illustrated on a two-dimensional input coordinate for describing a frequency-gain characteristic so that the illustrated waveform is arranged to undergo replacement input into a sequence of numbers corresponding therewith. Using the latter input technique, it is possible to input data while confirming the desired frequency-gain as an image. Therefore it is possible to make it easy to intuitively input the data expressing the desired frequency characteristic.

Several means for realizing the latter input technique can be considered. Such a method can be considered that, for example, a two-dimensional plane expressing a frequency-gain characteristic is displayed onto a display screen of a computer to illustrate the waveform of a desired frequency characteristic onto the two dimensional plane with a GUI (Graphical User Interface) and the like so as to make it into a numeric value data. In addition, instead of the GUI on a computer screen, a pointing device such as digitalizer, a plotter and the lime may be used. The technique nominated herein is only a simple example, a sequence of numbers may be arranged to be inputted with the other technique. In addition, here a desired frequency-gain characteristic is inputted as a sequence of numbers but may be inputted as a function expressing a waveform of the relevant frequency-gain characteristic.

Here, without using a window filter WF, an amplitude value expressing a frequency characteristic of a basic filter is inputted and undergoes the inverse FFT and thereby it is also possible to derive filter coefficients of the basic filter directly. However, in order to configure an ideal basic filter by an inverse FFT operation (in order to make an error from a desired frequency characteristic small), it is necessary to make the input data count corresponding to the filter coefficient counts extremely abundant. In that case, the filter coefficients configuring the basic filter will get huge in count and the filter coefficients as the final product generated by utilizing that will get huge in count. Accordingly, in case of desiring to make the filter coefficients as small as possible in count, the basic filter is preferably generated in use of a window filter WF as described above.

As described above, when the filter coefficients of the basic filter are derived, the filter coefficients of a plurality of frequency shift filters are further derived by the frequency shift operation. And, taking out one or more filters arbitrarily from a basic filter and a plurality of frequency shift filters, filter coefficients thereof having corresponding coefficient numbers are added to thereby derive new filter coefficients. It is possible to generate a digital filter having any frequency characteristic by arbitrarily changing the filter to be extracted.

And, for a sequence of numbers of the filter coefficients derived thereby, it is possible to significantly reduce unnecessary filter coefficients by rounding to reduce the bit count and to simplify the filter coefficients by conversion-to-integer processing. Accordingly, in order to decrease the number of filter coefficients, window multiplication as in a conventional case is not required. Since it is possible to design a digital filter without performing the window multiplication, no truncation error will occur to the frequency characteristic. Accordingly, it will become possible to improve the cut off characteristic to an extremely large extent so as to make available a filter characteristic with a phase characteristic being linear and excellent.

FIG. 47 shows an example of generating a lowpass filter having a trap in a part, and beside that, it is possible to generate a lowpass filter as well as a highpass filter, a bandpass filter and a band elimination filter having a pass range in any frequency band. Moreover, it is possible to generate a comb filter and a digital filter having the other special frequency characteristic. In addition, making the split number (β number) larger at the time of generating a basic filter, an inclination of a blocking range of the basic filter as well as an individual frequency shift filter gets larger and resolution for the filter designing area is enhanced. It is possible, therefore, to generate a digital filter precisely matching a desired frequency characteristic.

It is possible to realize an apparatus for realizing a filter designing method according to the third embodiment described so far with any of hardware configuration, DSP and software. For example, for realizing a filter designing apparatus in the present embodiment by software, it is actually configured by CPU or MPU, RAM, ROM and the like of a computer and can be realized by operating a program stored in the RAM, the ROM or the hard disc and the like.

For example, utilizing mathematical function of spreadsheet software installed in a personal computer and the like, it is also possible to perform an operation of deriving the basic filter, an operation of deriving the frequency shift filter and an operation of adding the filter coefficients of filters arbitrarily selected from the basic filter and a plurality of frequency shift filters. Operations in this case are actually performed by the CPU, the ROM, the RAM and the like of a personal computer and the like in which spreadsheet software is installed.

In addition, it is also advisable to calculate the filter coefficients of the basic filter and the filter coefficients of a plurality of frequency shift filters in advance to store them in a storage apparatus so that the CPU extracts and operates those selected by a user who operates a keyboard or a mouse. FIG. 49 is a block diagram showing a configuration example of a digital filter designing apparatus in that case.

In FIG. 49, reference numeral 61 denotes a filter coefficient table, which stores table data of a filter coefficient group (the filter coefficient group of the entire frequency band configuring a filter designing area) including filter coefficients of the above described basic filter and filter coefficients of a plurality of frequency shift filters. In the drawing, the numerals on the horizontal axis specify the filter number. That is, the column of the number 0 stores filter coefficients of the basic filter, while the columns of the number 1 and onward store filter coefficients of the frequency shift filters. Reference numeral 62 denotes a controller and controls the entire apparatus.

Reference numeral 63 denotes an operation part to select any one and more filters from the basic filter and a plurality of frequency shift filters. This operation part 63 is configured by an input device such as a keyboard, a mouse and the like. Reference numeral 64 denotes a display part, which displays a selection window at the time of selecting any one or more filters. This selection window may cause column numbers of the filter coefficient table 61 to be displayed to select any of them or may cause waveforms of frequency characteristics as in FIG. 46 to be displayed to select any thereof.

Reference numeral 65 denotes an calculation part to add filter coefficients (controller 12 reads from the filter coefficient table 11), which the operation part 63 selects out of the basic filter and a plurality of frequency shift filters, having corresponding coefficient numbers to thereby derive filter coefficients of a digital filter. This calculation part 65 also truncates off the lower bits for data of thus derived filter coefficients to perform, thereby, rounding on y-bits data to x bits and also multiply x-bits coefficient values by 2^{x} to round the fractional part.

Such configured digital filter designing apparatus derives and makes filter coefficients of the basic filter and a plurality of frequency shift filters and into table data in advance. Thereby it is possible for a user to operate the operation part 63 and select filter coefficients of filters so as to design a desired digital filter with only an extremely simple operation of simply adding them.

In case of actually implementing a digital filter inside an electronical device and semiconductor IC, as shown in FIG. 50 to FIG. 52, it is advisable to configure an FIR filter having a sequence of numbers finally derived as filter coefficients by a filter designing apparatus as described above. In that case, the number of the derived filter coefficients is significantly reduced by rounding and converted to simple integers. Accordingly, basically no multiplier is required and a bit shift circuit is applicable so that a desired frequency characteristic can be realized with a high accuracy in a small circuit size.

Here, basic filters and frequency shift filters may be configured as hardware respectively so that they are connected as hardware to mount a digital filter.

According to the third embodiment configured as described above, it is possible to accurately design a digital filter having an arbitrarily shaped frequency-gain characteristic with extremely simple processing of only selecting a desired one or more filters from the basic filter and a plurality of frequency shift filters generated from that and adding filter coefficients thereof. Moreover, it is possible to significantly reduce unnecessary filter coefficients by rounding and to simplify filter coefficients. Thereby, it is possible to configure a digital filter of realizing a desired frequency characteristic with a high accuracy in an extremely small circuit size.

Here, in the above described third embodiment, an example of using {−1, 0, 9, 16, 9, 0, −1} as a sequence of numbers of filter coefficients of the basic unit filter has been described, but the present invention will not be limited thereto. If the sequence of numbers is symmetric, it is applicable to the present invention.

In addition, in the above described third embodiment, there has been described an example in use of a lowpass filter as the basic filter, which undergoes frequency shift to the high frequency side, but the present invention will not be limited thereto. A highpass filter may be used as a basic filter so as to make it undergo frequency shift to the low frequency side or a bandpass filter may be used as a basic filter so as to make it undergo frequency shift to the high frequency side and the low frequency side.

In addition, in the above described third embodiment, the calculation part 65 may optionally weight filter coefficients of the relevant selected one or more filters respectively at the time of performing an operation by adding filter coefficients (those read by the controller 62 from the filter coefficient table 61) of one or more filters selected by the operation part 63 to calculate new filter coefficients. That will make it possible to design extremely simply a digital filter having an arbitrarily shaped frequency-gain characteristic subject to emphasis and attenuation only on a particular frequency band. In addition, it is also possible to simply design a graphic equalizer and the like in utilization of this characteristic.

Otherwise, any of the above described first to third embodiments only exemplify an embodying method of implementing the present invention and the technical scope of the present invention must not be interpreted in a limited fashion thereby. That is, the present invention can be implemented in various forms without departing from the spirit thereof or the major characteristics thereof.

### INDUSTRIAL APPLICABILITY

The present invention is useful for an FIR digital filter of a type of comprising tapped delay lines consisting of a plurality of delay devices and increasing several times in output signals of respective taps by respective coefficients and thereafter adding the result of those multiplications to output them.

1-48. (canceled)

49. A method of designing a digital filter, the method comprising:
a first step of calculating filter coefficients in case of combining and connecting arbitrarily in cascade connection more than one FIR-type basic filters having basic filter coefficients of sequence of numbers being a symmetric type with a total value of the relevant sequence of numbers being non zero and total value of numbers skipped by one in a sequence of numbers becomes equal each other with a same positive or negative sign, or basic filter coefficients of sequence of numbers being a symmetric type with a total value of the relevant sequence of numbers being zero and total value of numbers skipped by one in a sequence of numbers becomes equal each other with an opposite positive or negative sign;
a second step of reducing a bit count of filter coefficients to x bits (x<y) by implementing rounding to round lower bits for data having an absolute value falling within a range of not less than 0 and not more than 1 of y-bits filter coefficients calculated in said first step; and
a third step of second rounding of multiplying, by N, a value other than a power-of-two, filter coefficients in x-bits (x<y) derived in said second step, to round a fractional part so as to convert filter coefficients to integers.

50. A method of designing a digital filter, the method comprising:
a first step of calculating filter coefficients in case of combining and connecting arbitrarily in cascade connection more than one FIR-type basic filters having basic filter coefficients of sequence of numbers being a symmetric type with a total value of the relevant sequence of numbers being non zero and total value of numbers skipped by one in a sequence of numbers becomes equal each other with a same positive or negative sign, or basic filter coefficients of sequence of numbers being a symmetric type with a total value of the relevant sequence of numbers being zero and total value of numbers skipped by one in a sequence of numbers becomes equal each other with an opposite positive or negative sign; and
a second step of multiplying, by N, a value other than a power-of-two, data having an absolute value falling within a range of not less than 0 and not more than 1 of y-bits filter coefficients calculated in said first step to implement rounding a fractional part so as to derive a converted-to-integer filter coefficients in x-bits (x<y).

51. A method of designing a digital filter, the method comprising:
a first step of calculating filter coefficients in case of combining and connecting arbitrarily in cascade connection more than one FIR-type basic filters having basic filter coefficients of sequence of numbers being a symmetric type with a total value of the relevant sequence of numbers being non zero and total value of numbers skipped by one in a sequence of numbers becomes equal each other with a same positive or negative sign, or basic filter coefficients of sequence of numbers being a symmetric type with a total value of the relevant sequence of numbers being zero and total value of numbers skipped by one in a sequence of numbers becomes equal each other with an opposite positive or negative sign; and
a second step of regarding all data values having an absolute value falling within a range of not less than 0 and not more than 1 of y-bits filter coefficients calculated in said first step smaller than ½^{x} as zero and, as for the data values equal to or larger than ½^{x}, multiplies, by 2^{x+X}(x+X<y), said data values to undergo rounding on the fractional part to thereby derive (x+y)-bits converted-to-integer filter coefficients.

52. The method of claim 49, further comprising a fourth step and a fifth step between said first step and said second step, wherein:
said fourth step calculates symmetric second filter coefficients of realizing a second frequency-amplitude characteristic having a contact at a position imparting a local maximum value in a first frequency-amplitude characteristic expressed by said first filter coefficients calculated in said first step and imparting a local minimum value at the relevant contact;
said fifth step calculates third filter coefficients derived in case of connecting a first filter having said first filter coefficients and a second filter having said second filter coefficients;
said second step implements rounding to round lower bits for y-bits data of said third filter coefficients calculated in said fifth step to thereby derive x-bits (x<y) filter coefficients; and
said fourth step derives said second filter coefficients with an operation being {—kHₘ, −kHₘ₋₁, . . . , −kH₁, −kH₀+(1+k), −kH₋₁, . . . , −kH₋₍ₘ₋₁₎, −kH₋ₘ}, wherein k is any positive number, in the case where a sequence of numbers of said first filter coefficients is expressed by {Hₘ, Hₘ₋₁, . . . , H₁, H₀, H₋₁, . . . , H₋₍ₘ₋₁₎, H₋ₘ}.

53. A method of designing a digital filter, the method comprising:
a first step of generating a plurality of frequency shift filters by performing a frequency shift operation on a basic filter of realizing a frequency-amplitude characteristic having pass bandwidth of a share of sampling frequency divided by an integer to realize a frequency-amplitude characteristic of said basic filter subject to shift in every predetermined frequency so that the mutually adjacent filter groups overlap in the part of amplitude ½;
a second step of deriving new filter coefficients by extracting any one filter from a plurality of filters including said basic filter and said frequency shift filters, or by extracting any two or more filters from said plurality of filters and bringing filter coefficients corresponding to a same tap position of respective filter thereof into addition each other; and
a third step of reducing a bit count of filter coefficients by implementing rounding to round lower bits for data of filter coefficients calculated in said second step.

54. The method of claim 53, further comprising a fourth step of second rounding of multiplying, by N, a value other than a power-of-two, filter coefficients in x-bits (x<y) derived by implementing said rounding in said third step, on data having an absolute value falling within a range of not less than 0 and not more than 1 of y-bits filter coefficients calculated in said second step to round a fractional part so as to convert filter coefficients to integers.

55. The method of claim 53, wherein said third step multiplies, by N, a value other than a power-of-two, data having an absolute value falling within a range of not less than 0 and not more than 1 of y-bits filter coefficients calculated in said second step to implement rounding to round a fractional part to thereby derive x-bits (x<y) converted-to-integer filter coefficients.

56. The method of claim 53, wherein said third step regards all data values having an absolute value falling within a range of not less than 0 and not more than 1 of y-bits filter coefficients calculated in said second step smaller than ½^{x} as zero and, as for the data values equal to or larger than ½^{x}, multiplies, by 2^{x X}(x+X<y), said data values to undergo rounding on the fractional part to thereby derive (x+X)-bits converted-to-integer filter coefficients.

57. An apparatus for designing a digital filter, the apparatus comprising:
basic filter coefficient storage means for storing data on basic filter coefficients of sequence of numbers symmetric type with a total value of the relevant sequence of numbers being non zero and total value of numbers skipped by one in a sequence of numbers becomes equal each other with a same positive or negative sign, and basic filter coefficients of sequence of numbers symmetric type with a total value of the relevant sequence of numbers being zero and total value of numbers skipped by one in a sequence of numbers becomes equal each other with an opposite positive or negative sign; and
operation means for implementing an operation of calculating filter coefficients in case of combining and connecting arbitrarily in cascade connection more than one FIR-type basic filters having said basic filter coefficients with data stored in said basic filter coefficient storage means and an operation of reducing a bit count of filter coefficients to x bits (x<y) by implementing rounding to round lower bits for y-bits data having an absolute value falling within a range of not less than 0 and not more than 1 of the relevant calculated filter coefficients and an operation of second rounding of multiplying, by N, a value other than a power-of-two, the relevant calculated x-bits filter coefficients to round a fractional part so as to convert filter coefficients to integers.

58. An apparatus for designing a digital filter, the apparatus comprising:
basic filter coefficient storage means for storing data on basic filter coefficients of sequence of numbers symmetric type with a total value of the relevant sequence of numbers being non zero and total value of numbers skipped by one in a sequence of numbers becomes equal each other with a same positive or negative sign, and basic filter coefficients of sequence of numbers symmetric type with a total value of the relevant sequence of numbers being zero and total value of numbers skipped by one in a sequence of numbers becomes equal each other with an opposite positive or negative sign; and
operation means for implementing an operation of calculating filter coefficients in case of combining and connecting arbitrarily in cascade connection more than one FIR-type basic filters having said basic filter coefficients with data stored in said basic filter coefficient storage means and an operation of multiplying, by N, a value other than a power-of-two, y-bits data having an absolute value falling within a range of not less than 0 and not more than 1 of the relevant calculated filter coefficients to undergo rounding to round a fractional part so as to thereby derive convert-to-integer filter coefficients in x bits (x<y).

59. An apparatus for designing a digital filter, the apparatus comprising:
basic filter coefficient storage means for storing data on basic filter coefficients of sequence of numbers symmetric type with a total value of the relevant sequence of numbers being non zero and total value of numbers skipped by one in a sequence of numbers becomes equal each other with a same positive or negative sign, and basic filter coefficients of sequence of numbers symmetric type with a total value of the relevant sequence of numbers being zero and total value of numbers skipped by one in a sequence of numbers becomes equal each other with an opposite positive or negative sign; and
operation means for implementing an operation of calculating filter coefficients in case of combining and connecting arbitrarily in cascade connection more than one FIR-type basic filters having said basic filter coefficients with data stored in said basic filter coefficient storage means and an operation of regarding all y-bits data values having an absolute value falling within a range of not less than 0 and not more than 1 of filter coefficients smaller than ½^{x} as zero and, as for said data values equal to or larger than ½^{x}, multiplying, by 2^{x+X}(x+X<y), said data values to undergo rounding on the fractional part to thereby derive (x+X)-bits converted-to-integer filter coefficients.

60. An apparatus for designing a digital filter, the apparatus comprising:
basic filter coefficient storage means for storing data on basic filter coefficients of sequence of numbers symmetric type with a total value of the relevant sequence of numbers being non zero and total value of numbers skipped by one in a sequence of numbers becomes equal each other with a same positive or negative sign and basic filter coefficients of sequence of numbers symmetric type with a total value of the relevant sequence of numbers being zero and total value of numbers skipped by one in a sequence of numbers becomes equal each other with an opposite positive or negative sign; and
operation means for implementing an operation of calculating symmetric first filter coefficients derived in case of combining and connecting arbitrarily in cascade connection more than one FIR-type basic filters having said basic filter coefficients with data stored in said basic filter coefficient storage means; an operation of deriving symmetric second filter coefficients of realizing a second frequency-amplitude characteristic having a contact at a position imparting a local maximum value in a first frequency-amplitude characteristic expressed by said first filter coefficients and imparting a local minimum value at the relevant contact; an operation of deriving third filter coefficients derived in case of connecting a first filter having said first filter coefficients and a second filter having said second filter coefficients; and an operation of reducing a bit count of filter coefficients by implementing rounding to round lower bits for data of said third filter coefficients,
wherein said operation means derives said second filter coefficients with an operation being {−kHₘ, −kHₘ₋₁, . . . , −kH₁, −kH₀+(1+k), −kH₋₁, . . . , −kH₋₋₍ₘ₋₁₎, −kH₋ₘ}, wherein k is any positive number, in the case where a sequence of numbers of said first filter coefficients is expressed by {Hₘ, Hₘ₋₁, . . . , H₁, H₀, H₋₁, . . . , H₋₍ₘ₋₁₎, H₋ₘ}.

61. The apparatus of claim 60, wherein said operation means further comprises means for second rounding of multiplying, by N, a value other than a power-of-two, filter coefficients in x-bits (x<y) derived by implementing said rounding on data of said third filter coefficients in y-bits having an absolute value falling within a range of not less than 0 and not more than 1 to round a fractional part so as to convert filter coefficients to integers.

62. The apparatus of claim 60, wherein said operation means multiplies, by N, a value other than a power-of-two, the y-bits data having an absolute value falling within a range of not less than 0 and not more than 1 of said filter coefficients to implement rounding to round a fractional part to thereby derive x-bits (x<y) converted-to-integer filter coefficients.

63. The apparatus of claim 60, wherein said operation means regards all data values having an absolute value falling within a range of not less than 0 and not more than 1 in y-bits of said filter coefficients smaller than ½^{x} as zero and, as for the data values equal to or larger than ½^{x}, multiplies, by 2^{x+X}(x+X<y), said data values to undergo rounding on the fractional part to thereby derive (x+X)-bits converted-to-integer filter coefficients.

64. An apparatus for designing a digital filter, the apparatus comprising:
coefficient table storage means for storing table data of a filter coefficient group including filter coefficients of a basic filter realizing a frequency-amplitude characteristic having pass bandwidth of a share of sampling frequency divided by an integer and filter coefficients of a plurality of frequency shift filters realizing a frequency-amplitude characteristic of said basic filter subject to shift in every predetermined frequency so that the mutually adjacent filter groups overlap in the part of amplitude ½; and
operation means for performing an operation of calculating new filter coefficients by extracting filter coefficients of a designated one filter among a filter coefficient group stored in said coefficient table storage means, or by bringing filter coefficients corresponding to a same tap position of designated two or more filters among said filter coefficient group into addition each other and an operation of reducing a bit count of filter coefficients by implementing rounding to round the lower bits for the relevant calculated data of filter coefficients.

65. The apparatus of claim 64, wherein said operation means arbitrarily weights filter coefficients of said designated two or more filters respectively at the time of performing an operation by bringing filter coefficients of said designated two or more filters into addition to calculate new filter coefficients.

66. The apparatus of claim 64, wherein said operation means further comprises means for second rounding of multiplying, by N, a value other than a power-of-two, filter coefficients in x-bits (x<y) derived by implementing said rounding on y-bits filter coefficients data having an absolute value falling within a range of not less than 0 and not more than 1 of derived by an operation of calculating said new filter coefficients to round a fractional part so as to convert filter coefficients to integers.

67. The apparatus of claim 64, wherein said operation means multiplies by N, a value other than a power-of-two, the y-bits data having an absolute value to fall within a range of not less than 0 and not more than 1 of said filter coefficients to round a fractional part to thereby derive x-bits (x<y) converted-to-integer filter coefficients.

68. The apparatus of claim 64, wherein said operation means regards all y-bits data values (data with an absolute value to fall within a range of not less than 0 and not more than 1) of filter coefficients smaller than ½^{x} as zero and, as for said data values equal to or larger than ½^{x}, multiplies by 2^{x+X}(x+X<y), said data values to undergo rounding on the fractional part to thereby derive (x+X)-bits converted-to-integer filter coefficients.

69. A computer-readable medium containing instructions which, when executed by a computer, carryout the method of claim 49.

70. A computer-readable medium containing instructions which, when executed by a computer, carry out functions associated with the basic filter coefficient storage means and operation means of claim 57.

71. An FIR-type digital filter having, as filter coefficients, a sequence of numbers calculated according to the method of claim 49.

72. A digital filter, comprising:
a tapped delay line having a plurality of delay devices; and
means for multiplying, by several times, output signals of respective taps with filter coefficients derived in accordance with the method of claim 49 and, thereafter, adding a result of those multiplications to be outputted.

73. A digital filter, comprising:
a tapped delay line having a plurality of delay devices; and
means for multiplying, by several times, output signals of respective taps with filter coefficients derived in accordance with the method of claim 49 and, thereafter, adding a result of those multiplications and multiplying the added result by 1/N to be outputted.

74. A digital filter, comprising:
a tapped delay line having a plurality of delay devices; and
means for multiplying, by several times, output signals of respective taps with filter coefficients derived in accordance with the method of claim 51 and, thereafter, adding a result of those multiplications and multiplying the added result by ½^{x+X} to be outputted.

75. An FIR-type digital filter having, as filter coefficients, a sequence of numbers calculated according to the apparatus of claim 57.

76. A digital filter, comprising:
a tapped delay line having a plurality of delay devices; and
means for multiplying, by several times, output signals of respective taps with filter coefficients derived in accordance with the apparatus of claim 57 and, thereafter, adding a result of those multiplications to be outputted.

77. A digital filter, comprising:
a tapped delay line having a plurality of delay devices; and
means for multiplying, by several times, output signals of respective taps with filter coefficients derived in accordance with the apparatus of claim 57 and, thereafter, adding a result of those multiplications and multiplying the added result by 1/N to be outputted.

78. A digital filter, comprising:
a tapped delay line having a plurality of delay devices; and
means for multiplying, by several times, output signals of respective taps with filter coefficients derived in accordance with the apparatus of claim 59 and, thereafter, adding a result of those multiplications and multiplying the added result by ½^{x+X} to be outputted.
